(19) United States
(12) Patent Application Publication
(10) Pub. No.: US 2023/0303594 A1
(43) Pub. Date: Sep. 28, 2023

(54) ORGANIC MOLECULES FOR OPTOELECTRONIC DEVICES

(71) Applicant: CYNORA GMBH, Bruchsal (DE)

(72) Inventors: Stefan SEIFERMANN, Bühl (DE); Daniel ZINK, Graben-Neudorf (DE); Sebastian DÜCK, Heidelberg (DE)

(21) Appl. No.: 18/009,965

(22) PCT Filed: Jun. 16, 2021
(86) PCT No.: PCT/EP2021/066197

§ 371 Date: Dec. 12, 2022

(30) Foreign Application Priority Data
Jun. 18, 2020 (EP) 20180685.8

(51) Int. Cl. C07F 5/02; H10K 85/60; H10K 50/11; H10K 71/16

(52) U.S. Cl. CPC C07F 5/027; H10K 50/11; H10K 71/164; H10K 85/631; H10K 85/654; H10K 85/658; C07B 2200/05

(57) ABSTRACT

The invention relates to an organic molecule for the application in optoelectronic devices. According to the invention, the organic molecule has a structure of Formula I:

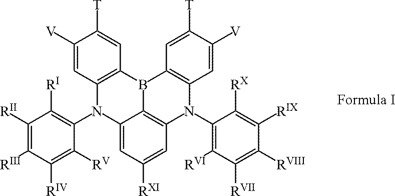

wherein
either both groups T are R¹ or both groups V are R¹ while the remaining groups T or V that are not R¹ are selected from the group consisting of hydrogen, deuterium, R¹, C₁-Cs-alkyl, and Ph (═ phenyl), which is optionally substituted with one or more substituents independently from each other selected from the group consisting of Me, ⁱPr, ^{t}Bu, and Ph;
R¹ is methyl, which is substituted with
two groups R⁶ and one phenyl, which is optionally substituted with R⁶:

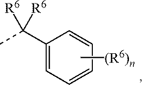

which is bonded via the position marked by the dotted line; and n is an integer, which is selected from the group consisting of 0, 1, 2, 3, 4 and 5.

### CROSS REFERENCE TO RELATED APPLICATIONS

This application is a U.S. National Phase Patent Application of International Patent Application Number PCT/EP2021/0066197, filed on Jun. 16, 2021, which claims priority to European Patent Application Number 20180685.8, filed on Jun. 18, 2020, the entire content of all of which is incorporated herein by reference.

The invention relates to organic light-emitting molecules and their use in organic light-emitting diodes (OLEDs) and in other optoelectronic devices.

### DESCRIPTION

The object of the present invention is to provide molecules which are suitable for use in optoelectronic devices.

This object is achieved by the invention which provides a new class of organic molecules.

According to the invention the organic molecules are purely organic molecules, i.e. they do not contain any metal ions in contrast to metal complexes known for the use in optoelectronic devices. The organic molecules of the invention, however, include metalloids, in particular B, Si, Sn, Se, and/or Ge.

According to the present invention, the organic molecules exhibit emission maxima in the blue, sky-blue or green spectral range. The organic molecules exhibit in particular emission maxima between 420 nm and 520 nm, preferably between 440 nm and 495 nm, more preferably between 450 nm and 470 nm. The photoluminescence quantum yields of the organic molecules according to the invention are, in particular, 50% or more. The use of the molecules according to the invention in an optoelectronic device, for example an organic light-emitting diode (OLED), leads to higher efficiencies or higher color purity, expressed by the full width at half maximum (FWHM) of the emission spectrum, of the device. Corresponding OLEDs have a higher stability than OLEDs with known emitter materials and comparable color.

The organic light-emitting molecules according to the invention include or consist a structure of Formula I,

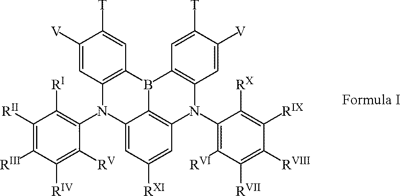

wherein
either both groups T are R¹ or both groups V are R¹ while the group T or V that is not R¹ is selected from the group consisting of:
hydrogen;
deuterium;
C₁-C₅-alkyl; and
Ph, which is optionally substituted with one or more substituents independently from each other selected from the group consisting of Me, ⁱPr, ^{t}Bu, and Ph;
wherein
R¹ has a structure of the following Formula F:

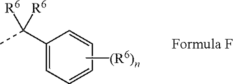

i.e. a methyl group, which is substituted with two groups R⁶ and one phenyl, which is optionally substituted with n R⁶, wherein n is an integer, which is at each occurrence selected from the group consisting of 0, 1, 2, 3, 4 and 5;
the dotted line in the Formula F marks the bonding position to the structure shown in Formula I;
R⁶ is at each occurrence independently from each other selected from the group consisting of:
hydrogen,
deuterium, and
C₁-C₅-alkyl;
R^{I}, R^{II}, R^{III}, R^{IV}, R^{V}, R^{VI}, R^{VII}, R^{VIII}, R^{IX} and R^{X} are independently from one another selected from the group consisting of:
R¹;
hydrogen;
deuterium;
N(R⁵)₂;
OR⁵;
SR⁵;
Si(R⁵)₃;
B(OR⁵)₂;
OSO₂R⁵;
CF₃;
CN;
halogen;
C₁-C₄₀-alkyl,
which is optionally substituted with one or more substituents R⁵ and
wherein one or more non-adjacent CH₂-groups are optionally substituted by R⁵C=CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-alkoxy,
which is optionally substituted with one or more substituents R⁵ and
wherein one or more non-adjacent CH₂-groups are optionally substituted by R⁵C=CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-thioalkoxy,
which is optionally substituted with one or more substituents R⁵ and
wherein one or more non-adjacent CH₂-groups are optionally substituted by R⁵C=CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkenyl,
which is optionally substituted with one or more substituents R⁵ and
wherein one or more non-adjacent CH₂-groups are optionally substituted by R⁵C=CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkynyl,
which is optionally substituted with one or more substituents R⁵ and
wherein one or more non-adjacent CH₂-groups are optionally substituted by R⁵C=CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀-aryl,
which is optionally substituted with one or more substituents R⁵; and
C₃-C₅₇-heteroaryl,
which is optionally substituted with one or more substituents R⁵;
R⁵ is at each occurrence independently from one another selected from the group consisting of: hydrogen, deuterium, OPh (Ph = phenyl), SPh, CF₃, CN, F, Si(C₁-C₅-alkyl)₃, Si(Ph)₃,
C₁-C₅-alkyl,
wherein optionally one or more hydrogen atoms are independently from each other substituted by deuterium, CN, CF₃, or F;
C₁-C₅-alkoxy,
wherein optionally one or more hydrogen atoms are independently from each other substituted by deuterium, CN, CF₃, or F;
C₁-C₅-thioalkoxy,
wherein optionally one or more hydrogen atoms are independently from each other substituted by deuterium, CN, CF₃, or F;
C₂-C₅-alkenyl,
wherein optionally one or more hydrogen atoms are independently from each other substituted by deuterium, CN, CF₃, or F;
C₂-C₅-alkynyl,
wherein optionally one or more hydrogen atoms are independently from each other substituted by deuterium, CN, CF₃, or F;
C₆-C₁₈-aryl,
which is optionally substituted with one or more C₁-C₅-alkyl substituents;
C₃-C₁₇-heteroaryl,
which is optionally substituted with one or more C₁-C₅-alkyl substituents;
N(C₆-C₁₈-aryl)₂;
N(C₃-C₁₇-heteroaryl)₂; and
N(C₃-C₁₇-heteroaryl)(C₆-C₁₈-aryl).
R^{XI} is selected from the group consisting of hydrogen, chloride and C₁-C₅ alkyl.

According to the invention, either both groups T are R¹ or both groups V are R¹. It is not possible that all variables T and V in Formula I are R¹.

Put differently, the organic molecule of the invention includes or consists of a structure selected from the group consisting of Formula Ia and Formula Ib:

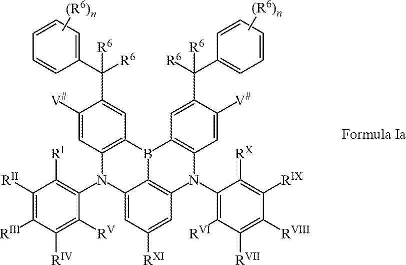

wherein
V^{#} is selected from the group consisting of:
hydrogen;
deuterium;
C₁-C₅-alkyl; and
Ph, which is optionally substituted with one or more substituents independently from each other selected from the group consisting of Me, ⁱPr, ^{t}Bu, and Ph.

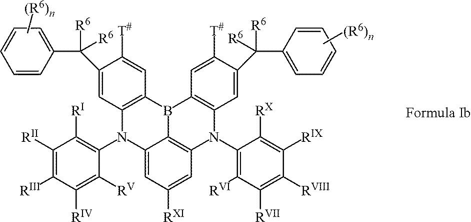

wherein
T^{#} is selected from the group consisting of:
Hydrogen;
Deuterium;
C₁-C₅-alkyl; and
Ph, which is optionally substituted with one or more substituents independently from each other selected from the group consisting of Me, ⁱPr, ^{t}Bu, and Ph.

According to the invention, R¹ is bonded via the position marked by the dotted line shown in Formula F, which means, Formula Ia is identically represented by

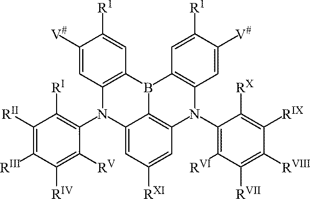

and Formula Ib is identically represented by

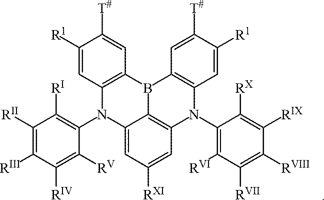

The organic molecule of the invention has at least two groups with a structure of Formula F, but may have up to 12 groups with a structure of Formula F. Certain embodiments of the organic molecule have two or four groups with a structure of Formula F.

In a preferred embodiment, the organic molecules include or consist of a structure selected from the group consisting of Formula Ia and Formula Ib, wherein T^{#} and V^{#} is selected from the group consisting of hydrogen, deuterium, Me, ⁱPr, ^{t}Bu, and

Ph, which is optionally substituted with one or more substituents independently from each other selected from the group consisting of Me, ⁱPr, ^{t}Bu, and Ph.

In a preferred embodiment, T and V are selected from the group consisting of:
R¹;
hydrogen, deuterium, Me, ⁱPr, ^{t}Bu; and
Ph, which is optionally substituted with one or more substituents independently from each other selected from the group consisting of Me, ⁱPr, ^{t}Bu, and Ph.

Depending on the value of the integer n, R¹ may have a structure as shown below:

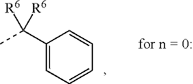

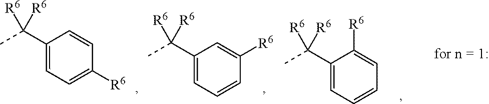

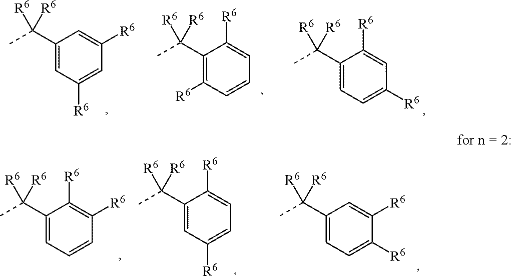

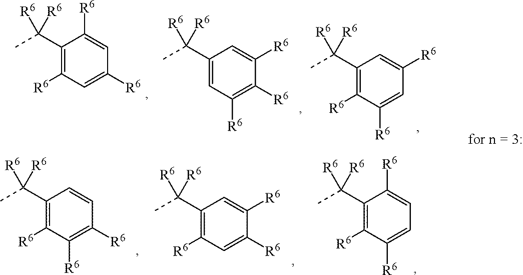

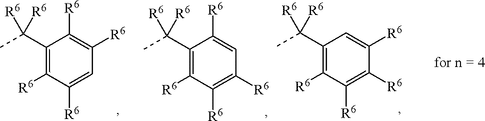

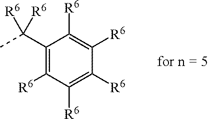

wherein R⁶ is at each occurrence independently from each other selected from the group consisting of: hydrogen, deuterium, and C₁-C₅-alkyl, wherein, in certain embodiments, the C₁-C₅-alkyl group may be Me, ⁱPr, ^{t}Bu, or neo-pentyl.

In certain embodiments, R⁶ is at each occurrence independently from each other selected from the group consisting of: hydrogen, deuterium, Me, ⁱPr, ^{t}Bu, and neo-pentyl.

In other embodiments, R⁶ is at each occurrence independently from each other selected from the group consisting of: hydrogen and Me.

In a preferred embodiment, R¹ is at each occurrence selected from the group consisting of Formula R^{1a} and Formula R^{1b}:

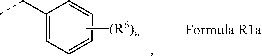

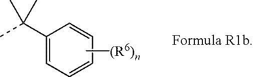

Specific examples of R¹ include for example:

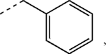

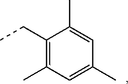

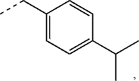

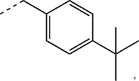

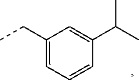

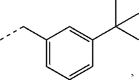

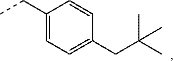

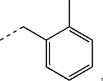

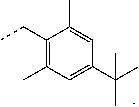

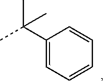

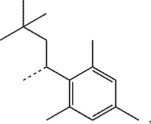

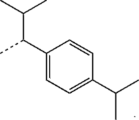

In one particularly preferred embodiment, R¹ is selected from the group consisting of Formula R^{1c} and Formula R^{1d}:

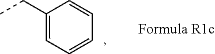

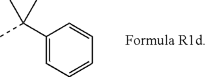

In one embodiment, R^{XI} is selected from the group of hydrogen, Me, ⁱPr and ^{t}Bu.

In one embodiment, R^{XI} is hydrogen or Me.

In one embodiment, R^{XI} is hydrogen.

In one embodiment, R^{XI} is chloride.

In one embodiment, R^{XI} is Me.

In one embodiment of the organic molecule, R^{I}, R^{II}, R^{III}, R^{IV}, R^{V}, R^{VI}, R^{VII}, R^{VIII}, R^{IX} and R^{X} are independently from one another selected from the group consisting of:
R¹,
hydrogen, deuterium, halogen, Me, ⁱPr, ^{t}Bu, CN, CF₃, SiMes, SiPh₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

In one embodiment, R^{I}, R^{II}, R^{III}, R^{IV}, R^{V}, R^{VI}, R^{VII}, R^{VIII}, R^{IX} and R^{X} are independently from one another selected from the group consisting of:
R¹,
hydrogen, deuterium, halogen, Me, ⁱPr, ^{t}Bu, CN, CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

In one embodiment, R^{I}, R^{II}, R^{III}, R^{IV}, R^{V}, R^{VI}, R^{VII}, R^{VIII}, R^{IX} and R^{X} are independently from one another selected from the group consisting of:
R¹, hydrogen, deuterium, halogen, Me, ⁱPr, ^{t}Bu, CN, CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph, and
triazinyl, which is optionally substituted with one or more substituents independently from each other selected from the group consisting of Me, ⁱPr, ^{t}Bu, CN, CF₃, and Ph, and
N(Ph)₂.

In one embodiment, R^{I}, R^{II}, R^{III}, R^{IV}, R^{V}, R^{VI}, R^{VII}, R^{VIII}, R^{IX} and R^{X} are independently from one another selected from the group consisting of: R¹, hydrogen, deuterium, Me, ⁱPr, ^{t}Bu,
Ph, which is optionally substituted with one or more substituents independently from each other selected from the group consisting of Me, ⁱPr, ^{t}Bu, and Ph,
carbazolyl, which is optionally substituted with one or more substituents independently from each other selected from the group consisting of Me, ⁱPr, ^{t}Bu, CN, CF₃, and Ph, and
N(Ph)₂.

In one embodiment R^{I}, R^{II}, R^{III}, R^{IV}, R^{V}, R^{VI}, R^{VII}, R^{VIII}, R^{IX} and R^{X} are independently from one another selected from the group consisting of: R¹, hydrogen, deuterium, Me, ⁱPr, ^{t}Bu,
Ph, which is optionally substituted with one or more substituents independently from each other selected from the group consisting of Me, ⁱPr, ^{t}Bu, and Ph, and
N(Ph)₂.

In one embodiment, R^{I}, R^{II}, R^{III}, R^{IV}, R^{V}, R^{VI}, R^{VII}, R^{VIII}, R^{IX} and R^{X} are independently from one another selected from the group consisting of: R¹, hydrogen, deuterium, Me, ⁱPr, ^{t}Bu,
Ph, which is optionally substituted with one or more substituents independently from each other selected from the group consisting of Me, ⁱPr, ^{t}Bu, and Ph, and
N(Ph)₂.

In one embodiment, R^{I}, R^{II}, R^{III}, R^{IV}, R^{V}, R^{VI}, R^{VII}, R^{VIII}, R^{IX} and R^{X} are independently from one another selected from the group consisting of: R¹, hydrogen, ^{t}Bu, and Ph.

In one embodiment of the invention, R^{X} = R^{I}, R^{IX} = R^{II}, R^{VIII} = R^{III}, R^{VII} = R^{IV}, and R^{V} = R^{VI} which yields an organic molecule including or consisting of a structure of Formula II:

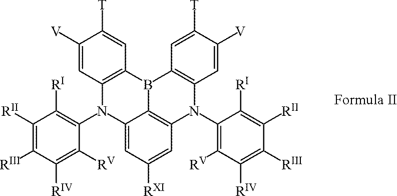

In one embodiment, the organic molecules include or consist of a structure of Formula II, wherein R^{I}, R^{II}, R^{III}, R^{IV}, and R^{V} are independently from one another selected from the group consisting of:
R¹,
hydrogen, deuterium, halogen, Me, ⁱPr, ^{t}Bu, CN, CF₃, SiMe₃, SiPh₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

In one embodiment, the organic molecules include or consist of Formula II, wherein R^{I}, R^{II}, R^{III}, R^{IV}, and R^{V} are independently from one another selected from the group consisting of:
R¹,
hydrogen, deuterium, halogen, Me, ⁱPr, ^{t}Bu, CN, CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

In one embodiment, the organic molecules include or consist of Formula II, wherein R^{I}, R^{II}, R^{III}, R^{IV}, and R^{V} are independently from one another selected from the group consisting of:
R¹, hydrogen, deuterium, halogen, Me, ⁱPr, ^{t}Bu, CN, CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

In one embodiment, the organic molecules include or consist of Formula II, wherein R^{I}, R^{II}, R^{III}, R^{IV}, and R^{V} are independently from one another selected from the group consisting of: R¹, hydrogen, deuterium, Me, ⁱPr, ^{t}Bu,
Ph, which is optionally substituted with one or more substituents independently from each other selected from the group consisting of Me, ⁱPr, ^{t}Bu, and Ph,
carbazolyl, which is optionally substituted with one or more substituents independently from each other selected from the group consisting of Me, ⁱPr, ^{t}Bu, CN, CF₃, and Ph, and
N(Ph)₂.

In one embodiment, the organic molecules include or consist of Formula II, wherein R^{I}, R^{II}, R^{III}, R^{IV}, and R^{V} are independently from one another selected from the group consisting of: R¹, hydrogen, deuterium, Me, ⁱPr, ^{t}Bu,
Ph, which is optionally substituted with one or more substituents independently from each other selected from the group consisting of Me, ⁱPr, ^{t}Bu, and Ph, and
N(Ph)₂.

In one embodiment, the organic molecules include or consist of Formula II, wherein R^{I}, R^{II}, R^{III}, R^{IV}, and R^{V} are independently from one another selected from the group consisting of: R¹, hydrogen, deuterium, Me, ⁱPr, ^{t}Bu,
Ph, which is optionally substituted with one or more substituents independently from each other selected from the group consisting of Me, ⁱPr, ^{t}Bu, and Ph, and
N(Ph)₂.

In one embodiment, the organic molecules include or consist of Formula II, wherein R^{I}, R^{II}, R^{III}, R^{IV}, and R^{V} are independently from one another selected from the group consisting of: R¹, hydrogen, ^{t}Bu, and Ph.

In one embodiment, the organic molecules include or consist of a structure selected from the group consisting of Formula II-1 and Formula II-2:

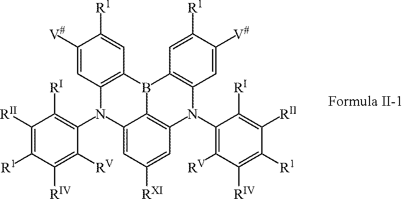

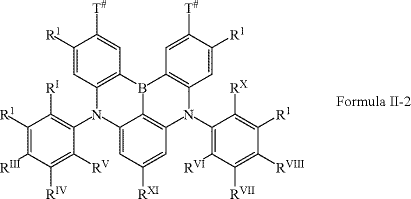

Examples of the organic molecules according to the invention, which include or consist of a structure selected from the group consisting of Formula II-1 and Formula II-2 are shown below:

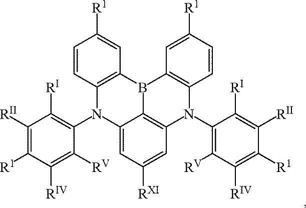

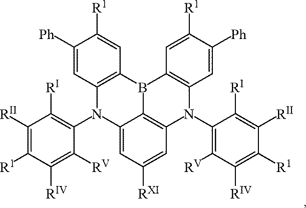

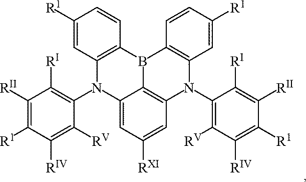

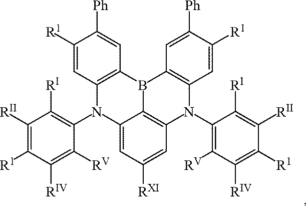

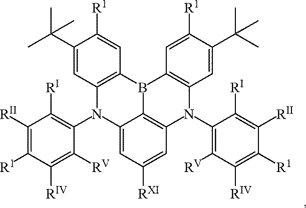

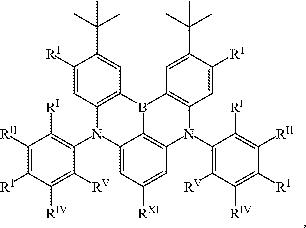

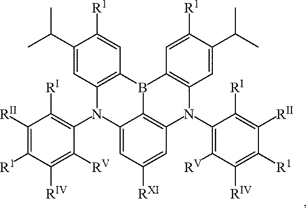

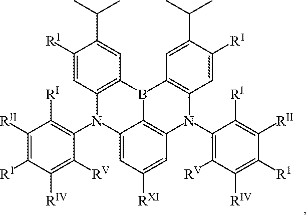

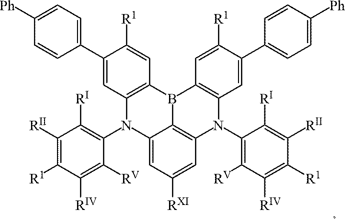

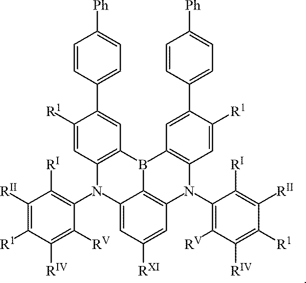

In certain embodiments of the invention, the organic molecules include or consist of a structure selected from the group consisting of Formula IIa, Formula IIb, Formula IIc, and Formula IId:

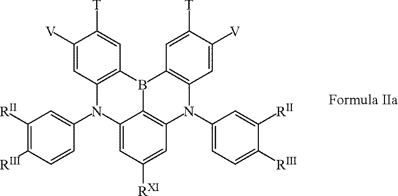

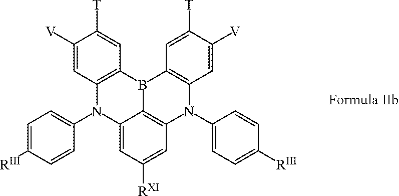

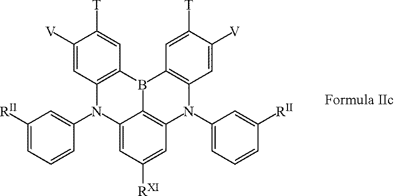

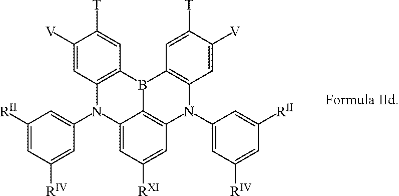

Examples for organic molecules including or consisting of a structure selected from the group consisting of Formula IIa, Formula IIb, Formula IIc, and Formula IId are shown below:

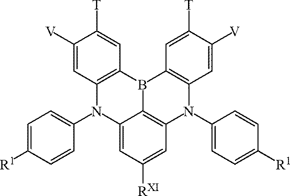

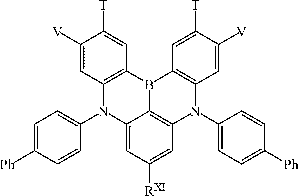

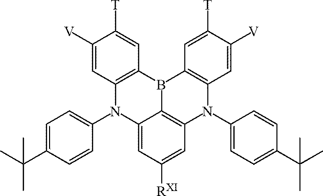

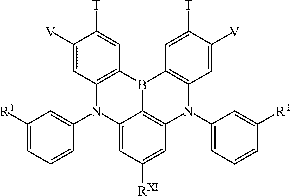

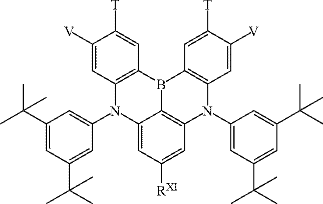

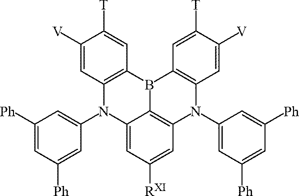

In one embodiment, the organic molecules include or consist of a structure selected from the group consisting of Formula IIIa and Formula IIIb:

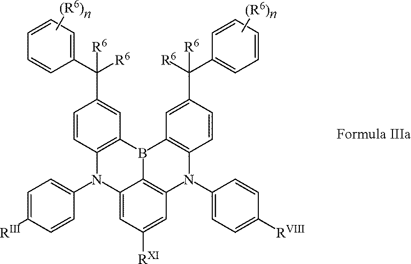

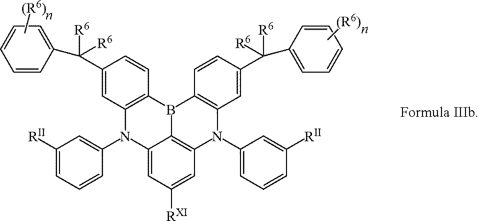

In a preferred embodiment, the organic molecules include or consist of a structure selected from the group consisting of Formula IIIa-1 and Formula IIIb-1:

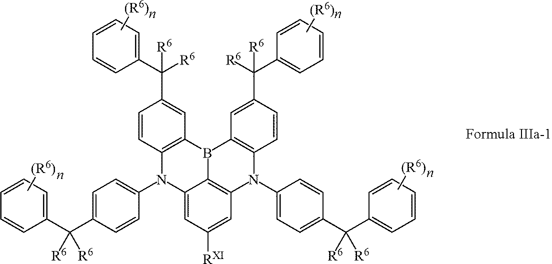

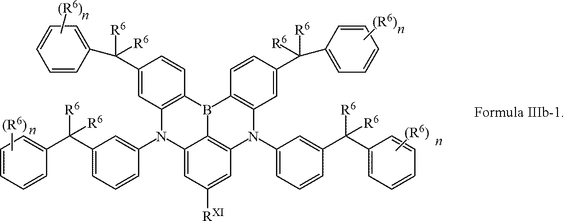

In one embodiment, the organic molecule includes or consists of a structure selected from the group consisting of Formula IV-1 and Formula IV-2:

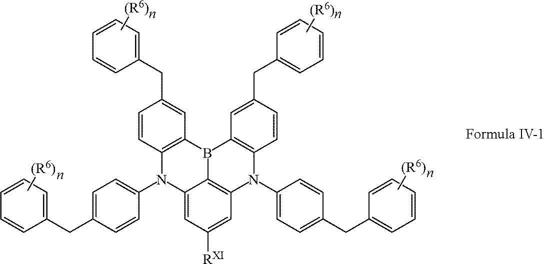

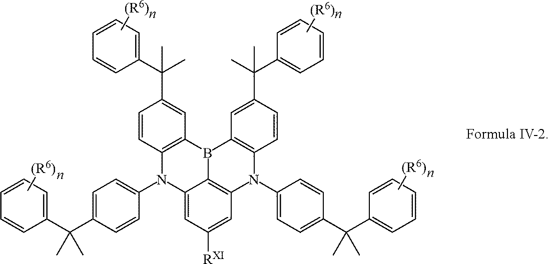

In one embodiment, the organic molecule includes or consists of a structure selected from the group consisting of Formula IVa and Formula IVb:

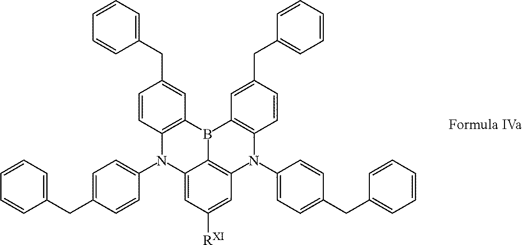

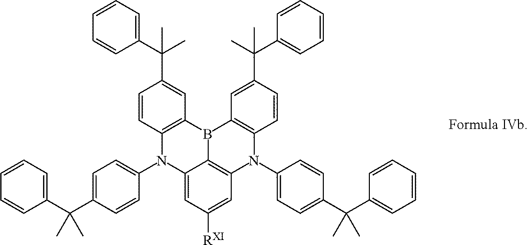

In one embodiment, the organic molecule includes or consists of a structure selected from the group consisting of Formula IV-3 and Formula IV-4:

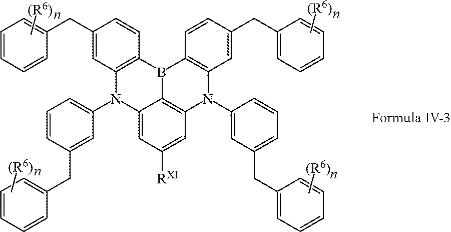

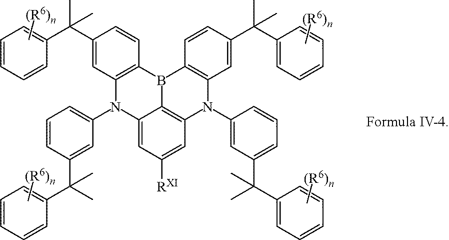

In one embodiment, the organic molecule includes or consists of a structure selected from the group consisting of Formula IVc and Formula IVd:

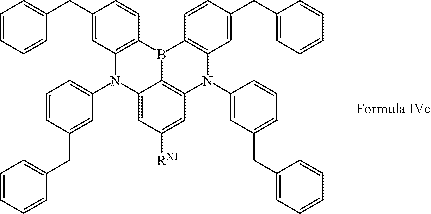

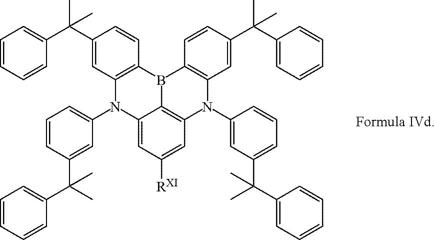

As used throughout the present application, the terms “aryl” and “aromatic” may be understood in the broadest sense as any mono-, bi- or polycyclic aromatic moieties. Accordingly, an aryl group contains 6 to 60 aromatic ring atoms, and a heteroaryl group contains 5 to 60 aromatic ring atoms, of which at least one is a heteroatom. Notwithstanding, throughout the application the number of aromatic ring atoms may be given as subscripted number in the definition of certain substituents. In particular, the heteroaromatic ring includes one to three heteroatoms. Again, the terms “heteroaryl” and “heteroaromatic” may be understood in the broadest sense as any mono-, bi- or polycyclic hetero-aromatic moieties that include at least one heteroatom. The heteroatoms may at each occurrence be the same or different and be individually selected from the group consisting of N, O and S. Accordingly, the term “arylene” refers to a divalent substituent that bears two binding sites to other molecular structures and thereby serving as a linker structure. In case, a group in the exemplary embodiments is defined differently from the definitions given here, for example, the number of aromatic ring atoms or number of heteroatoms differs from the given definition, the definition in the exemplary embodiments is to be applied. According to the invention, a condensed (annulated) aromatic or heteroaromatic polycycle is built of two or more single aromatic or heteroaromatic cycles, which formed the polycycle via a condensation reaction.

In particular, as used throughout, the term “aryl group or heteroaryl group” includes groups which can be bound via any position of the aromatic or heteroaromatic group, derived from benzene, naphthalene, anthracene, phenanthrene, pyrene, dihydropyrene, chrysene, perylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene; pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthoimidazole, phenanthroimidazole, pyridoimidazole, pyrazinoimidazole, quinoxalinoimidazole, oxazole, benzoxazole, naphthooxazole, anthroxazol, phenanthroxazol, isoxazole, 1,2-thiazole, 1,3-thiazole, benzothiazole, pyridazine, benzopyridazine, pyrimidine, benzopyrimidine, 1,3,5-triazine, quinoxaline, pyrazine, phenazine, naphthyridine, carboline, benzocarboline, phenanthroline, 1,2,3-triazole, 1,2,4-triazole, benzotriazole, 1,2,3-oxadiazole, 1,2,4-oxadiazole, 1,2,5-oxadiazole, 1,2,3,4-tetrazine, purine, pteridine, indolizine and benzothiadiazole, or combinations of the above mentioned groups.

As used throughout, the term “cyclic group” may be understood in the broadest sense as any mono-, bi- or polycyclic moieties.

As used throughout, the term “biphenyl” as a substituent may be understood in the broadest sense as ortho-biphenyl, meta-biphenyl, or para-biphenyl, wherein ortho, meta and para are defined in regard to the binding site to another chemical moiety.

As used throughout, the term “alkyl group” may be understood in the broadest sense as any linear, branched, or cyclic alkyl substituent. In particular, examples of the term alkyl include the substituents methyl (Me), ethyl (Et), n-propyl (ⁿPr), i-propyl (ⁱPr), cyclopropyl, n-butyl (ⁿBu), i-butyl (ⁱBu), s-butyl (^{s}Bu), t-butyl (^{t}Bu), cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]-octyl, 2-(2,6-dimethyl)octyl, 3-(3,7-dimethyl)octyl, adamantyl, 2,2,2-trifluorethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)-cyclohex-1-yl, 1-(n-butyl)-cyclohex-1-yl, 1-(n-hexyl)-cyclohex-1-yl, 1-(n-octyl)-cyclohex-1-yl and 1-(n-decyl)-cyclohex-1-yl.

As used throughout, the term “alkenyl” includes linear, branched, and cyclic alkenyl substituents. The term “alkenyl group”, for example, includes the substituents ethenyl, propenyl, butenyl, pentenyl, cyclopentenyl, hexenyl, cyclohexenyl, heptenyl, cycloheptenyl, octenyl, cyclooctenyl or cyclooctadienyl.

As used throughout, the term “alkynyl” includes linear, branched, and cyclic alkynyl substituents. The term “alkynyl group”, for example, includes ethynyl, propynyl, butynyl, pentynyl, hexynyl, heptynyl or octynyl.

As used throughout, the term “alkoxy” includes linear, branched, and cyclic alkoxy substituents. Examples of the term “alkoxy group” include methoxy, ethoxy, n-propoxy, i-propoxy, n-butoxy, i-butoxy, s-butoxy, t-butoxy and 2-methylbutoxy.

As used throughout, the term “thioalkoxy” includes linear, branched, and cyclic thioalkoxy substituents, in which the O of the exemplary alkoxy groups is replaced by S.

As used throughout, the terms “halogen” and “halo” may be understood in the broadest sense as being preferably fluorine, chlorine, bromine or iodine.

Whenever hydrogen (H) is mentioned herein, it could also be replaced by deuterium at each occurrence.

It is understood that when a molecular fragment is described as being a substituent or otherwise attached to another moiety, its name may be written as if it were a fragment (e.g. naphthyl, dibenzofuryl) or as if it were the whole molecule (e.g. naphthalene, dibenzofuran). As used herein, these different ways of designating a substituent or attached fragment are considered to be equivalent.

In one embodiment, the organic molecules according to the invention have an excited state lifetime of not more than 150 µs, of not more than 100 µs, in particular of not more than 50 µs, more preferably of not more than 10 µs or not more than 7 µs in a film of poly(methyl methacrylate) (PMMA) with 2% by weight of the organic molecule at room temperature.

In a further embodiment of the invention, the organic molecules according to the invention have an emission peak in the visible or nearest ultraviolet range, i.e., in the range of a wavelength of from 380 nm to 800 nm, with a full width at half maximum of less than 0.23 eV, preferably less than 0.20 eV, more preferably less than 0.19 eV, even more preferably less than 0.18 eV or even less than 0.17 eV in a film of poly(methyl methacrylate) (PMMA) with 2% by weight of the organic molecule at room temperature.

Orbital and excited state energies can be determined either by means of experimental methods. The energy of the highest occupied molecular orbital E^{HOMO} is determined by methods known to the person skilled in the art from cyclic voltammetry measurements with an accuracy of 0.1 eV. The energy of the lowest unoccupied molecular orbital E^{LUMO} is calculated as E^{HOMO} + E^{gap}, wherein E^{gap} is determined as follows: For host compounds, the onset of the emission spectrum of a film with 10% by weight of host in poly(methyl methacrylate) (PMMA) is used as E^{gap}, unless stated otherwise. For emitter molecules, E^{gap} is determined as the energy at which the excitation and emission spectra of a film with 10% by weight of emitter in PMMA cross. For the organic molecules according to the invention, E^{gap} is determined as the energy at which the excitation and emission spectra of a film with 2% by weight of emitter in PMMA cross.

The energy of the first excited triplet state T1 is determined from the onset of the emission spectrum at low temperature, typically at 77 K. For host compounds, where the first excited singlet state and the lowest triplet state are energetically separated by > 0.4 eV, the phosphorescence is usually visible in a steady-state spectrum in 2-Me-THF. The triplet energy can thus be determined as the onset of the phosphorescence spectrum. For TADF emitter molecules, the energy of the first excited triplet state T1 is determined from the onset of the delayed emission spectrum at 77 K, if not otherwise stated, measured in a film of PMMA with 10% by weight of emitter and in case of the organic molecules according to the invention with 2% by weight of the organic molecules according to the invention. Both for host and emitter compounds, the energy of the first excited singlet state S1 is determined from the onset of the emission spectrum, if not otherwise stated, measured in a film of PMMA with 10% by weight of host or emitter compound and in case of the organic molecules according to the invention with 2% by weight of the organic molecules according to the invention.

The onset of an emission spectrum is determined by computing the intersection of the tangent to the emission spectrum with the x-axis. The tangent to the emission spectrum is set at the high-energy side of the emission band and at the point at half maximum of the maximum intensity of the emission spectrum.

In one embodiment, the organic molecules according to the invention have an onset of the emission spectrum, which is energetically close to the emission maximum, i.e. the energy difference between the onset of the emission spectrum and the energy of the emission maximum is below 0.14 eV, preferably below 0.13 eV, or even below 0.12 eV, while the full width at half maximum (FWHM) of the organic molecules is less than 0.23 eV, preferably less than 0.20 eV, more preferably less than 0.19 eV, even more preferably less than 0.18 eV or even less than 0.17 eV in a film of poly(methyl methacrylate) (PMMA) with 2 % by weight of the organic molecule at room temperature, resulting in a CIEy coordinate below 0.20, preferably below 0.18, more preferably below 0.16 or even more preferably below 0.14.

A further aspect of the invention relates to the use of an organic molecule of the invention as a luminescent emitter or as an absorber, and/or as a host material and/or as an electron transport material, and/or as a hole injection material, and/or as a hole blocking material in an optoelectronic device.

A preferred embodiment relates to the use of an organic molecule according to the invention as a luminescent emitter in an optoelectronic device.

The optoelectronic device may be understood in the broadest sense as any device based on organic materials that is suitable for emitting light in the visible or nearest ultraviolet (UV) range, i.e., in the range of a wavelength of from 380 to 800 nm. More preferably, the optoelectronic device may be able to emit light in the visible range, i.e., of from 400 nm to 800 nm.

In the context of such use, the optoelectronic device is more particularly selected from the group consisting of:
organic light-emitting diodes (OLEDs),
light-emitting electrochemical cells,
OLED sensors, especially in gas and vapor sensors that are not hermetically shielded to the surroundings,
organic diodes,
organic solar cells,
organic transistors,
organic field-effect transistors,
organic lasers, and
down-conversion elements.

In a preferred embodiment in the context of such use, the optoelectronic device is a device selected from the group consisting of an organic light emitting diode (OLED), a light emitting electrochemical cell (LEC), and a light-emitting transistor.

In the case of the use, the fraction of the organic molecule according to the invention in the emission layer in an optoelectronic device, more particularly in an OLED, is 0.1% to 99% by weight, more particularly 1% to 80% by weight. In an alternative embodiment, the proportion of the organic molecule in the emission layer is 100% by weight.

In one embodiment, the light-emitting layer includes not only the organic molecules according to the invention, but also a host material whose triplet (T1) and singlet (S1) energy levels are energetically higher than the triplet (T1) and singlet (S1) energy levels of the organic molecule.

A further aspect of the invention relates to a composition including or consisting of:
(a) at least one organic molecule according to the invention, in particular in the form of an emitter and/or a host, and
(b) one or more emitter and/or host materials, which differ from the organic molecule according to the invention and
(c) optional one or more dyes and/or one or more solvents.

In one embodiment, the light-emitting layer includes (or essentially consists of) a composition including or consisting of:
(a) at least one organic molecule according to the invention, in particular in the form of an emitter and/or a host, and
(b) one or more emitter and/or host materials, which differ from the organic molecule according to the invention and
(c) optional one or more dyes and/or one or more solvents.

In a particular embodiment, the light-emitting layer EML includes (or essentially consists of) a composition including or consisting of:
(i) 0.1-10% by weight, preferably 0.5-5% by weight, in particular 1-3% by weight, of one or more organic molecules according to the invention;
(ii) 5-99% by weight, preferably 15-85% by weight, in particular 20-75% by weight, of at least one host compound H; and
(iii) 0.9-94.9% by weight, preferably 14.5-80% by weight, in particular 24-77% by weight, of at least one further host compound D with a structure differing from the structure of the molecules according to the invention; and
(iv)optionally 0-94% by weight, preferably 0-65% by weight, in particular 0-50% by weight, of a solvent; and
(v) optionally 0-30% by weight, in particular 0-20% by weight, preferably 0-5 % by weight, of at least one further emitter molecule F with a structure differing from the structure of the molecules according to the invention.

Preferably, energy can be transferred from the host compound H to the one or more organic molecules according to the invention, in particular transferred from the first excited triplet state T1(H) of the host compound H to the first excited triplet state T1(E) of the one or more organic molecules according to the invention E and/ or from the first excited singlet state S1(H) of the host compound H to the first excited singlet state S1(E) of the one or more organic molecules according to the invention E.

In one embodiment, the host compound H has a highest occupied molecular orbital HOMO(H) having an energy E^{HOMO}(H) in the range of from -5 to -6.5 eV and the at least one further host compound D has a highest occupied molecular orbital HOMO(D) having an energy E^{HOMO}(D), wherein E^{HOMO}(H) > E^{HOMO}(D).

In a further embodiment, the host compound H has a lowest unoccupied molecular orbital LUMO(H) having an energy E^{LUMO}(H) and the at least one further host compound D has a lowest unoccupied molecular orbital LUMO(D) having an energy E^{LUMO}(D), wherein E^{LUMO}(H) > E^{LUMO}(D).

In one embodiment, the host compound H has a highest occupied molecular orbital HOMO(H) having an energy E^{HOMO}(H) and a lowest unoccupied molecular orbital LUMO(H) having an energy E^{LUMO}(H), and
the at least one further host compound D has a highest occupied molecular orbital HOMO(D) having an energy E^{HOMO}(D) and a lowest unoccupied molecular orbital LUMO(D) having an energy E^{LUMO}(D),
the organic molecule according to the invention E has a highest occupied molecular orbital HOMO(E) having an energy E^{HOMO}(E) and a lowest unoccupied molecular orbital LUMO(E) having an energy E^{LUMO}(E),
wherein
E^{HOMO}(H) > E^{HOMO}(D) and the difference between the energy level of the highest occupied molecular orbital HOMO(E) of the organic molecule according to the invention E (E^{HOMO}(E)) and the energy level of the highest occupied molecular orbital HOMO(H) of the host compound H (E^{HOMO}(H)) is between -0.5 eV and 0.5 eV, more preferably between -0.3 eV and 0.3 eV, even more preferably between -0.2 eV and 0.2 eV or even between -0.1 eV and 0.1 eV; and
E^{LUMO}(H) > E^{LUMO}(D) and the difference between the energy level of the lowest unoccupied molecular orbital LUMO(E) of the organic molecule according to the invention E (E^{LUMO}(E)) and the energy level of the lowest unoccupied molecular orbital LUMO(D) of the at least one further host compound D (E^{LUMO}(D)) is between -0.5 eV and 0.5 eV, more preferably between -0.3 eV and 0.3 eV, even more preferably between -0.2 eV and 0.2 eV or even between -0.1 eV and 0.1 eV.

In one embodiment of the invention the host compound D and/ or the host compound H is a thermally-activated delayed fluorescence (TADF)-material. TADF materials exhibit a ΔE_{ST} value, which corresponds to the energy difference between the first excited singlet state (S1) and the first excited triplet state (T1), of less than 2500 cm⁻¹. Preferably the TADF material exhibits a ΔE_{ST} value of less than 3000 cm⁻¹, more preferably less than 1500 cm⁻¹, even more preferably less than 1000 cm⁻¹ or even less than 500 cm⁻¹.

In one embodiment, the host compound D is a TADF material and the host compound H exhibits a ΔE_{ST} value of more than 2500 cm⁻¹. In a particular embodiment, the host compound D is a TADF material and the host compound H is selected from group consisting of CBP, mCP, mCBP, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole.

In one embodiment, the host compound H is a TADF material and the host compound D exhibits a ΔE_{ST} value of more than 2500 cm⁻¹. In a particular embodiment, the host compound H is a TADF material and the host compound D is selected from group consisting of T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine).

In a further aspect, the invention relates to an optoelectronic device including an organic molecule or a composition of the type described here, more particularly in the form of a device selected from the group consisting of organic light-emitting diode (OLED), light-emitting electrochemical cell, OLED sensor, more particularly gas and vapour sensors not hermetically externally shielded, organic diode, organic solar cell, organic transistor, organic field-effect transistor, organic laser and down-conversion element.

In a preferred embodiment, the optoelectronic device is a device selected from the group consisting of an organic light emitting diode (OLED), a light emitting electrochemical cell (LEC), and a light-emitting transistor.

In one embodiment of the optoelectronic device of the invention, the organic molecule according to the invention E is used as emission material in a light-emitting layer EML.

In one embodiment of the optoelectronic device of the invention, the light-emitting layer EML consists of the composition according to the invention described here.

When the optoelectronic device is an OLED, it may, for example, have the following layer structure:
1. substrate
2. anode layer, A
3. hole injection layer, HIL
4. hole transport layer, HTL
5. electron blocking layer, EBL
6. emitting layer, EML
7. hole blocking layer, HBL
8. electron transport layer, ETL
9. electron injection layer, EIL
10. cathode layer, C
wherein the OLED only optionally includes each layer selected from the group of HIL, HTL, EBL, HBL, ETL, and EIL, and the different layers may be merged together into, e.g., one or more layers, and the OLED may include more than one layer of each layer type defined above.

Furthermore, the optoelectronic device may, in one embodiment, include one or more protective layers protecting the device from damaging exposure to harmful species in the environment including, for example, moisture, vapor and/or gases.

In one embodiment of the invention, the optoelectronic device is an OLED, with the following inverted layer structure:
1. substrate
2. cathode layer, C
3. electron injection layer, EIL
4. electron transport layer, ETL
5. hole blocking layer, HBL
6. emitting layer, EML
7. electron blocking layer, EBL
8. hole transport layer, HTL
9. hole injection layer, HIL
10. anode layer, A
wherein the OLED only optionally includes each layer selected from the group of HIL, HTL, EBL, HBL, ETL, and EIL, and the different layers may be merged into, e.g., one or more layers, and the OLED may include more than one layer of each layer types defined above.

In one embodiment of the invention, the optoelectronic device is an OLED, which may have a stacked architecture. In this architecture, contrary to the typical arrangement in which the OLEDs are placed side by side, the individual units are stacked on top of each other. Blended light may be generated with OLEDs exhibiting a stacked architecture, in particular white light may be generated by stacking blue, green and red OLEDs. Furthermore, the OLED exhibiting a stacked architecture may include a charge generation layer (CGL), which is typically located between two OLED subunits and typically consists of an n-doped layer and a p-doped layer with the n-doped layer of one CGL being typically located closer to the anode layer.

In one embodiment of the invention, the optoelectronic device is an OLED, which includes two or more emission layers between anode and cathode. In particular, this so-called tandem OLED includes three emission layers, wherein one emission layer emits red light, one emission layer emits green light and one emission layer emits blue light, and optionally may include further layers such as charge generation layers, blocking or transporting layers between the individual emission layers. In a further embodiment, the emission layers are adjacently stacked. In a further embodiment, the tandem OLED includes a charge generation layer between each two emission layers. In addition, adjacent emission layers or emission layers separated by a charge generation layer may be merged.

The substrate may be formed by any material or composition of materials. Most frequently, glass slides are used as substrates. Alternatively, thin metal layers (e.g., copper, gold, silver or aluminum films) or plastic films or slides may be used. This may allow for a higher degree of flexibility. The anode layer A is mostly composed of materials allowing to obtain an (essentially) transparent film. As at least one of the two electrodes should be (essentially) transparent in order to allow light emission from the OLED, either the anode layer A or the cathode layer C is transparent. Preferably, the anode layer A includes a large content or even consists of transparent conductive oxides (TCOs). Such anode layer A may, for example, include indium tin oxide, aluminum zinc oxide, fluorine doped tin oxide, indium zinc oxide, PbO, SnO, zirconium oxide, molybdenum oxide, vanadium oxide, tungsten oxide, graphite, doped Si, doped Ge, doped GaAs, doped polyaniline, doped polypyrrol and/or doped polythiophene.

The anode layer A (essentially) may consist of indium tin oxide (ITO) (e.g., (lnO₃)_{0.9}(SnO₂)_{0.1}). The roughness of the anode layer A caused by the transparent conductive oxides (TCOs) may be compensated by using a hole injection layer (HIL). Further, the HIL may facilitate the injection of quasi charge carriers (i.e., holes) in that the transport of the quasi charge carriers from the TCO to the hole transport layer (HTL) is facilitated. The hole injection layer (HIL) may include poly-3,4-ethylenedioxy thiophene (PEDOT), polystyrene sulfonate (PSS), MoO₂, V₂O₅, CuPC or Cul, in particular a mixture of PEDOT and PSS. The hole injection layer (HIL) may also prevent the diffusion of metals from the anode layer A into the hole transport layer (HTL). The HIL may, for example, include PEDOT:PSS (poly-3,4-ethylenedioxy thiophene: polystyrene sulfonate), PEDOT (poly-3,4-ethylenedioxy thiophene), mMTDATA (4,4′,4″-tris[phenyl(m-tolyl)amino]triphenylamine), Spiro-TAD (2,2′,7,7′-tetrakis(n,n-diphenylamino)-9,9′-spirobifluorene), DNTPD (N1,N1′-(biphenyl-4,4′-diyl)bis(N1-phenyl-N4,N4-di-m-tolylbenzene-1,4-diamine), NPB (N,N′-nis-(1-naphthalenyl)-N,N′-bis-phenyl-(1,1′-biphenyl)-4,4′-diamine), NPNPB (N,N′-diphenyl-N,N′-di-[4-(N,N-diphenyl-amino)phenyl]benzidine), MeO-TPD (N,N,N′,N′-tetrakis(4-methoxyphenyl)benzidine), HAT-CN (1,4,5,8,9,11-hexaazatriphenylen-hexacarbonitrile) and/or Spiro-NPD (N,N′-diphenyl-N,N′-bis-(1-naphthyl)-9,9′-spirobifluorene-2,7-diamine).

Adjacent to the anode layer A or hole injection layer (HIL), a hole transport layer (HTL) is typically located. Herein, any hole transport compound may be used. For example, electron-rich heteroaromatic compounds such as triarylamines and/or carbazoles may be used as hole transport compound. The HTL may decrease the energy barrier between the anode layer A and the light-emitting layer EML. The hole transport layer (HTL) may also be an electron blocking layer (EBL). Preferably, hole transport compounds bear comparably high energy levels of their triplet states T1. For example, the hole transport layer (HTL) may include a star-shaped heterocycle such as tris(4-carbazoyl-9-ylphenyl)amine (TCTA), poly-TPD (poly(4-butylphenyl-diphenylamine)), [alpha]-NPD (poly(4-butylphenyl-diphenyl-amine)), TAPC (4,4′-cyclohexyliden-bis[N,N-bis(4-methylphenyl)benzenamine]), 2-TNATA (4,4′,4″-tris[2-naphthyl(phenyl)amino]triphenylamine), Spiro-TAD, DNTPD, NPB, NPNPB, MeO-TPD, HAT-CN and/or Tris-Pcz (9,9′-diphenyl-6-(9-phenyl-9H-carbazol-3-yl)-9H,9′H-3,3′-bicarbazole). In addition, the HTL may include a p-doped layer, which may be composed of an inorganic or organic dopant in an organic hole-transporting matrix. Transition metal oxides such as vanadium oxide, molybdenum oxide or tungsten oxide may, for example, be used as the inorganic dopant.

Tetrafluorotetracyanoquinodimethane (F₄-TCNQ), copper-pentafluorobenzoate (Cu(I)pFBz) or transition metal complexes may, for example, be used as the organic dopant.

The EBL may, for example, include mCP (1,3-bis(carbazol-9-yl)benzene), TCTA, 2-TNATA, mCBP (3,3-di(9H-carbazol-9-yl)biphenyl), tris-Pcz, CzSi (9-(4-tert-Butylphenyl)-3,6-bis(triphenylsilyl)-9H-carbazole), and/or DCB (N,N′-dicarbazolyl-1,4-dimethylbenzene).

Adjacent to the hole transport layer (HTL), the light-emitting layer EML is typically located. The light-emitting layer EML includes at least one light emitting molecule. Particularly, the EML includes at least one light emitting molecule according to the invention E. In one embodiment, the light-emitting layer includes only the organic molecules according to the invention. Typically, the EML additionally includes one or more host materials H. For example, the host material H is selected from CBP (4,4′-Bis-(N-carbazolyl)-biphenyl), mCP, mCBP Sif87 (dibenzo[b,d]thiophen-2-yltriphenylsilane), CzSi, Sif88 (dibenzo[b,d]thiophen-2-yl)diphenylsilane), DPEPO (bis[2-(diphenylphosphino)phenyl] ether oxide), 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, 9-[3,5-bis(2-dibenzothiophenyl)phenyl]-9H-carbazole, T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine). The host material H typically should be selected to exhibit first triplet (T1) and first singlet (S1) energy levels, which are energetically higher than the first triplet (T1) and first singlet (S1) energy levels of the organic molecule.

In one embodiment of the invention, the EML includes a so-called mixed-host system with at least one hole-dominant host and one electron-dominant host. In a particular embodiment, the EML includes exactly one light emitting organic molecule according to the invention and a mixed-host system including T2T as the electron-dominant host and a host selected from CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole as the hole-dominant host. In a further embodiment the EML includes 50-80% by weight, preferably 60-75% by weight of a host selected from CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole; 10-45% by weight, preferably 15-30% by weight of T2T and 5-40% by weight, preferably 10-30% by weight of light emitting molecule according to the invention.

Adjacent to the light-emitting layer EML, an electron transport layer (ETL) may be located. Herein, any electron transporter may be used. Exemplarily, electron-poor compounds such as, e.g., benzimidazoles, pyridines, triazoles, oxadiazoles (e.g., 1,3,4-oxadiazole), phosphinoxides and sulfone, may be used. An electron transporter may also be a star-shaped heterocycle such as 1,3,5-tri(1-phenyl-1H-benzo[d]imidazol-2-yl)phenyl (TPBi). The ETL may include NBphen (2,9-bis(naphthalen-2-yl)-4,7-diphenyl-1,10-phenanthroline), Alq₃ (Aluminum-tris(8-hydroxyquinoline)), TSPO1 (diphenyl-4-triphenylsilylphenyl-phosphinoxide), BPyTP2 (2,7-di(2,2′-bipyridin-5-yl)triphenyle), Sif87 (dibenzo[b,d]thiophen-2-yltriphenylsilane), Sif88 (dibenzo[b,d]thiophen-2-yl)diphenylsilane), BmPyPhB (1,3-bis[3,5-di(pyridin-3-yl)phenyl]benzene) and/or BTB (4,4′-bis-[2-(4,6-diphenyl-1,3,5-triazinyl)]-1,1′-biphenyl). Optionally, the ETL may be doped with materials such as Liq. The electron transport layer (ETL) may also block holes or a hole blocking layer (HBL) is introduced. The HBL may, for example, include BCP (2,9-dimethyl-4,7-diphenyl-1,10-phenanthroline = Bathocuproine), BAlq (bis(8-hydroxy-2-methylquinoline)-(4-phenylphenoxy)aluminum), NBphen (2,9-bis(naphthalen-2-yl)-4,7-diphenyl-1,10-phenanthroline), Alq₃ (Aluminum-tris(8-hydroxyquinoline)), TSPO1 (diphenyl-4-triphenylsilylphenyl-phosphinoxide), T2T (2,4,6-tris(biphenyl-3-yl)-1,3,5-triazine), T3T (2,4,6-tris(triphenyl-3-yl)-1,3,5-triazine), TST (2,4,6-tris(9,9′-spirobifluorene-2-yl)-1,3,5-triazine), and/or TCB/TCP (1,3,5-tris(N-carbazolyl)benzol/1,3,5-tris(carbazol)-9-yl) benzene).

Adjacent to the electron transport layer (ETL), a cathode layer C may be located. The cathode layer C may, for example, include or may consist of a metal (e.g., Al, Au, Ag, Pt, Cu, Zn, Ni, Fe, Pb, LiF, Ca, Ba, Mg, In, W, or Pd) or a metal alloy. For practical reasons, the cathode layer may also consist of (essentially) intransparent metals such as Mg, Ca or Al. Alternatively or additionally, the cathode layer C may also include graphite and or carbon nanotubes (CNTs). Alternatively, the cathode layer C may also consist of nanoscalic silver wires.

An OLED may further, optionally, include a protection layer between the electron transport layer (ETL) and the cathode layer C (which may be designated as electron injection layer (EIL)). This layer may include lithium fluoride, cesium fluoride, silver, Liq (8-hydroxyquinolinolatolithium), Li₂O, BaF₂, MgO and/or NaF.

Optionally, the electron transport layer (ETL) and/or a hole blocking layer (HBL) may also include one or more host compounds H.

In order to modify the emission spectrum and/or the absorption spectrum of the light-emitting layer EML further, the light-emitting layer EML may further include one or more additional emitter molecules F. Such an emitter molecule F may be any emitter molecule known in the art. Preferably such an emitter molecule F is a molecule with a structure differing from the structure of the molecules according to the invention E. The emitter molecule F may optionally be a TADF emitter. Alternatively, the emitter molecule F may optionally be a fluorescent and/or phosphorescent emitter molecule which is able to shift the emission spectrum and/or the absorption spectrum of the light-emitting layer EML. Exemplarily, the triplet and/or singlet excitons may be transferred from the organic emitter molecule according to the invention to the emitter molecule F before relaxing to the ground state S0 by emitting light typically red-shifted in comparison to the light emitted by an organic molecule. Optionally, the emitter molecule F may also provoke two-photon effects (i.e., the absorption of two photons of half the energy of the absorption maximum).

Optionally, an optoelectronic device (e.g., an OLED) may, for example, be an essentially white optoelectronic device. For example, such white optoelectronic device may include at least one (deep) blue emitter molecule and one or more emitter molecules emitting green and/or red light. Then, there may also optionally be energy transmittance between two or more molecules as described above.

As used herein, if not defined more specifically in the particular context, the designation of the colors of emitted and/or absorbed light is as follows:

| | |
|---|---|
| violet: | wavelength range of >380-420 nm; |
| deep blue: | wavelength range of >420-480 nm; |
| sky blue: | wavelength range of >480-500 nm; |
| green: | wavelength range of >500-560 nm; |
| yellow: | wavelength range of >560-580 nm; |
| orange: | wavelength range of >580-620 nm; |
| red: | wavelength range of >620-800 nm. |

With respect to emitter molecules, such colors refer to the emission maximum. Therefore, for example, a deep blue emitter has an emission maximum in the range of from >420 to 480 nm, a sky blue emitter has an emission maximum in the range of from >480 to 500 nm, a green emitter has an emission maximum in a range of from >500 to 560 nm, and a red emitter has an emission maximum in a range of from >620 to 800 nm.

A deep blue emitter may preferably have an emission maximum of below 480 nm, more preferably below 470 nm, even more preferably below 465 nm or even below 460 nm. It will typically be above 420 nm, preferably above 430 nm, more preferably above 440 nm or even above 450 nm.

Accordingly, a further aspect of the present invention relates to an OLED, which exhibits an external quantum efficiency at 1000 cd/m² of more than 8%, more preferably of more than 10%, more preferably of more than 13%, even more preferably of more than 15% or even more than 20% and/or exhibits an emission maximum between 420 nm and 500 nm, preferably between 430 nm and 490 nm, more preferably between 440 nm and 480 nm, even more preferably between 450 nm and 470 nm and/or exhibits a LT80 value at 500 cd/m² of more than 100 h, preferably more than 200 h, more preferably more than 400 h, even more preferably more than 750 h or even more than 1000 h. Accordingly, a further aspect of the present invention relates to an OLED, whose emission exhibits a CIEy color coordinate of less than 0.45, preferably less than 0.30, more preferably less than 0.20 or even more preferably less than 0.15 or even less than 0.10.

A further aspect of the present invention relates to an OLED, which emits light at a distinct color point. According to the present invention, the OLED emits light with a narrow emission band (small full width at half maximum (FWHM)). In one aspect, the OLED according to the invention emits light with a FWHM of the main emission peak of less than 0.30 eV, preferably less than 0.25 eV, more preferably less than 0.20 eV, even more preferably less than 0.19 eV or even less than 0.17 eV.

A further aspect of the present invention relates to an OLED, which emits light with CIEx and ClEy color coordinates close to the CIEx (= 0.131) and ClEy (= 0.046) color coordinates of the primary color blue (CIEx = 0.131 and ClEy = 0.046) as defined by ITU-R Recommendation BT.2020 (Rec. 2020) and thus is suited for the use in Ultra High Definition (UHD) displays, e.g. UHD-TVs. Accordingly, a further aspect of the present invention relates to an OLED, whose emission exhibits a CIEx color coordinate of between 0.02 and 0.30, preferably between 0.03 and 0.25, more preferably between 0.05 and 0.20 or even more preferably between 0.08 and 0.18 or even between 0.10 and 0.15 and/ or a CIEy color coordinate of between 0.00 and 0.45, preferably between 0.01 and 0.30, more preferably between 0.02 and 0.20 or even more preferably between 0.03 and 0.15 or even between 0.04 and 0.10.

In a further aspect, the invention relates to a method for producing an optoelectronic component. In this case an organic molecule of the invention is used.

The optoelectronic device, in particular the OLED according to the present invention can be fabricated by any means of vapor deposition and/ or liquid processing. Accordingly, at least one layer is
prepared by means of a sublimation process,
prepared by means of an organic vapor phase deposition process,
prepared by means of a carrier gas sublimation process, and/or
solution processed or printed.

The methods used to fabricate the optoelectronic device, in particular the OLED according to the present invention are known in the art. The different layers are individually and successively deposited on a suitable substrate by means of subsequent deposition processes. The individual layers may be deposited using the same or differing deposition methods.

Vapor deposition processes, for example, include thermal (co)evaporation, chemical vapor deposition and physical vapor deposition. For active matrix OLED display, an AMOLED backplane is used as substrate. The individual layer may be processed from solutions or dispersions employing adequate solvents. Solution deposition process, for example, includes spin coating, dip coating and jet printing. Liquid processing may optionally be carried out in an inert atmosphere (e.g., in a nitrogen atmosphere) and the solvent may be completely or partially removed by means known in the state of the art.

### EXAMPLES

### General Synthesis Scheme I

General synthesis scheme I provides a synthesis scheme for organic molecules according to the invention wherein R^{X} = R^{I}, R^{IX} = R^{II}, R^{VIII} = R^{III}, R^{VII} = R^{IV}, and R^{V} = R^{VI}:

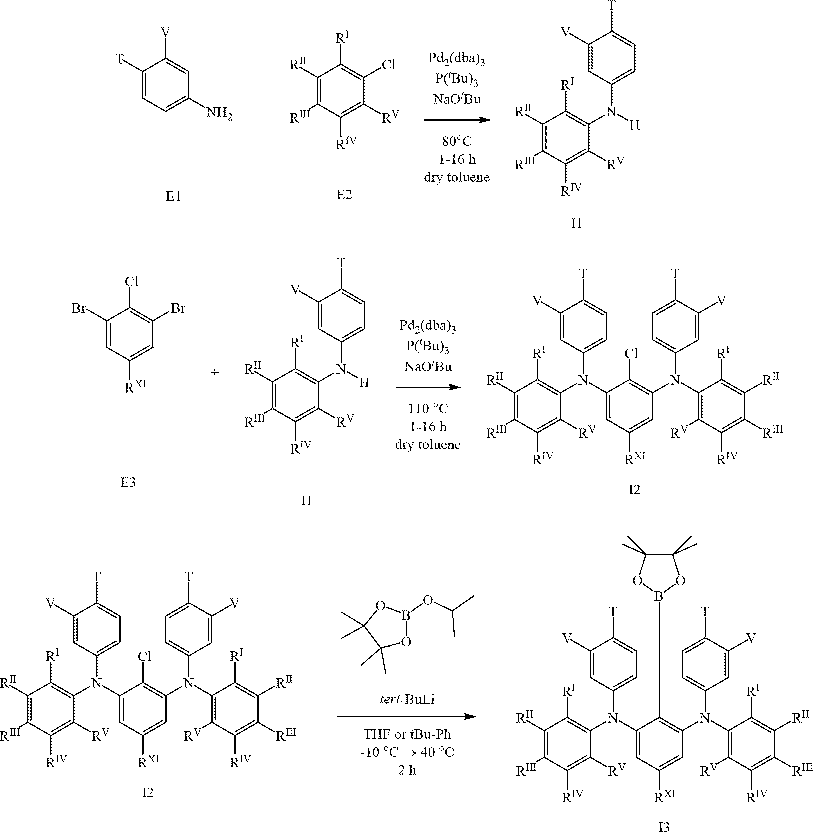

Alternatively, trimethyl borate may be used as borylating reagent yielding the boronic acid derivatives corresponding to I3.

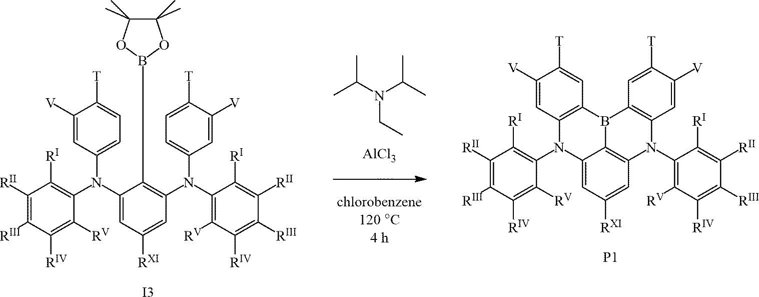

Alternatively, the corresponding boronic acid derivative of substrate I3 might be used as starting material under the same conditions.

### Alternative One-Pot Ring Closure Scheme Directly Converting I2 to P1.

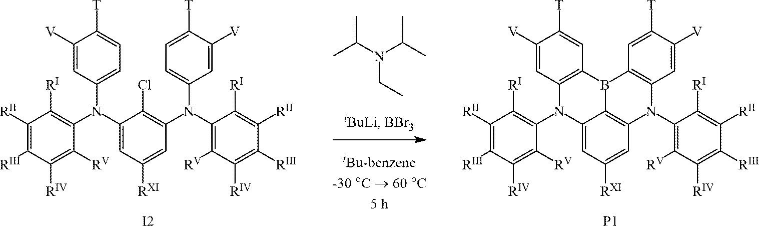

### General Procedure for Synthesis AAV1

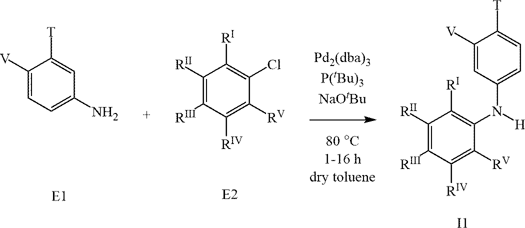

E1 (1.00 equivalents), E2 (1.10 equivalents), tris(dibenzylideneacetone)dipalladium Pd₂(dba)₃ (0.01 equivalents; CAS: 51364-51-3), tri-tert-butyl-phosphine (P(^{t}Bu)₃, CAS: 13716-12-6, 0.04 equivalents) and sodium tert-butoxide (NaO^{t}Bu; 1.70 equivalents) were stirred under nitrogen atmosphere in toluene at 80° C. for 1-16 h. After cooling down to room temperature (rt) the reaction mixture was extracted with toluene and water and the phases were separated. The combined organic layers were dried over MgSO₄ and then the solvent was removed under reduced pressure. The crude product obtained was purified by recrystallization or column chromatography and I1 was obtained as a solid or an oil.

### General Procedure for Synthesis AAV2

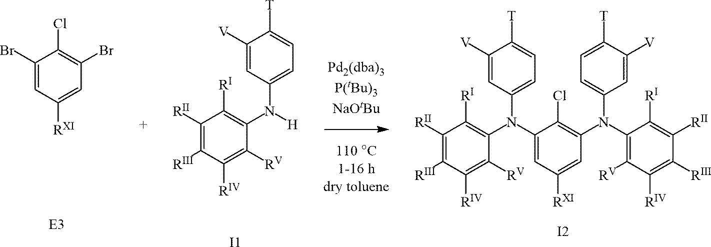

I1 (2.20 equivalents), E3 (1.00 equivalents), tris(dibenzylideneacetone)-dipalladium Pd₂(dba)₃ (0.02 equivalents; CAS: 51364-51-3), tri-tert-butyl-phosphine (0.08 equivalents, P(^{t}Bu)₃, CAS: 13716-12-6) and sodium tert-butoxide (NaO^{t}Bu; 3.30 equivalents) were stirred under nitrogen atmosphere in toluene at 110° C. for 1-16 h. After cooling down to room temperature (rt) the reaction mixture was extracted with toluene and water and the phases were separated. The combined organic layers were dried over MgSO₄ and then the solvent was removed under reduced pressure. The crude product obtained was purified by recrystallization or column chromatography and I2 was obtained as a solid.

### General Procedure for Synthesis AAV3

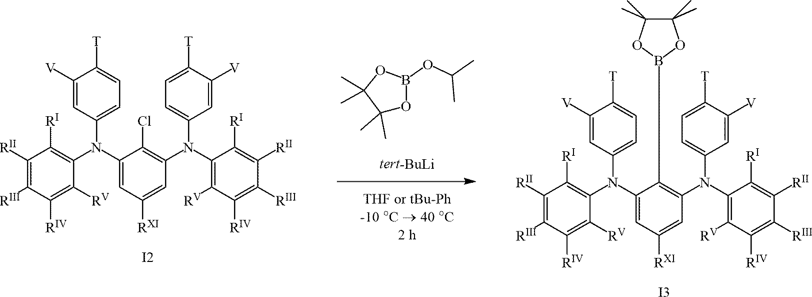

Under nitrogen atmosphere I2 (1.00 equivalent) was dissolved in dry THF. The resulting solution was cooled down to -10° C. Subsequently, tert-BuLi (2.20 equivalents, CAS: 594-19-4) was slowly added and stirring was continued at 0° C. After complete lithiation, 1,3,2-dioxaborolane (3.00 equivalents, CAS: 61676-62-8 or alternatively trimethyl borate, CAS 121-43-7) was added, followed by heating at 40° C. for 2 h. After cooling down to room temperature (rt), water was added and the phases were separated. The combined organic layers were dried over MgSO₄, filtered and concentrated under reduced pressure. The crude product obtained was purified by recrystallization or column chromatography to yield I3 or the corresponding boronic acid derivative, respectively, as a solid.

### General Procedure for Synthesis AAV4

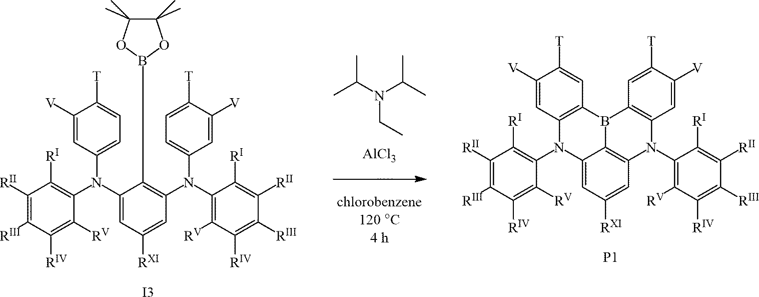

I3 (1.00 equivalent), N,N-diisopropylethylamine (10 equivalents, CAS: 7087-68-5) and AlCl₃ (10 equivalents, CAS: 7446-70-0) were stirred under nitrogen atmosphere in chlorobenzene at 120° C. for 4 h. After cooling down to room temperature (rt) the reaction mixture was extracted between toluene and water and the phases were separated. The combined organic layers were dried over MgSO₄ and then the solvent was removed under reduced pressure. The crude product obtained was purified by recrystallization or column chromatography and P1 was obtained as a solid.

### General Procedure for Synthesis AAV5

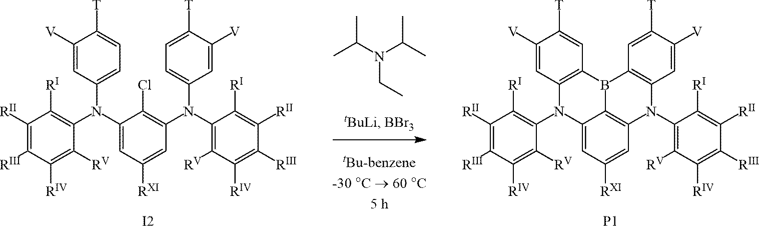

I2 (1.00 equivalents) was dissolved in tert-butylbenzene under nitrogen atmosphere and the solution was cooled to -30° C. A solution of tert-butyllithium (^{t}BuLi) (2.20 equivalents, CAS: 594-19-4) was added dropwise and the reaction mixture was allowed to warm up to 0° C. After stirring for 120 minutes at 60° C., the solvent of the ^{t}BuLi -solution and byproducts were removed under reduced pressure and the reaction mixture was cooled again to -30° C. A solution of boron tribromide (BBr₃, CAS: 10294-33-4, 2.20 equivalents) was added dropwise, the cooling bath was removed and the reaction mixture was allowed to warm up to room temperature (rt). After stirring for 30 minutes at rt, the reaction mixture was cooled to 0° C. and N,N-diisopropylethylamine (CAS: 7087-68-5, 3.00 equivalents) was added. The reaction mixture was allowed to warm up to rt and then heated at reflux at 120° C. for 3 h. Subsequently, the reaction mixture was poured into water and the resulting precipitate was filtered and washed with a minimum amount of ethyl acetate to obtain P1 as a solid product. P1 can be further purified by recrystallization or by flash chromatography.

### General Synthesis Scheme II

General synthesis scheme II provides a synthesis scheme for organic molecules according to the invention, wherein R^{X} = R^{I}, R^{IX} = R^{II}, R^{VIII} = R^{III}, R^{VII} = R^{IV}, and R^{V} = R^{VI}:

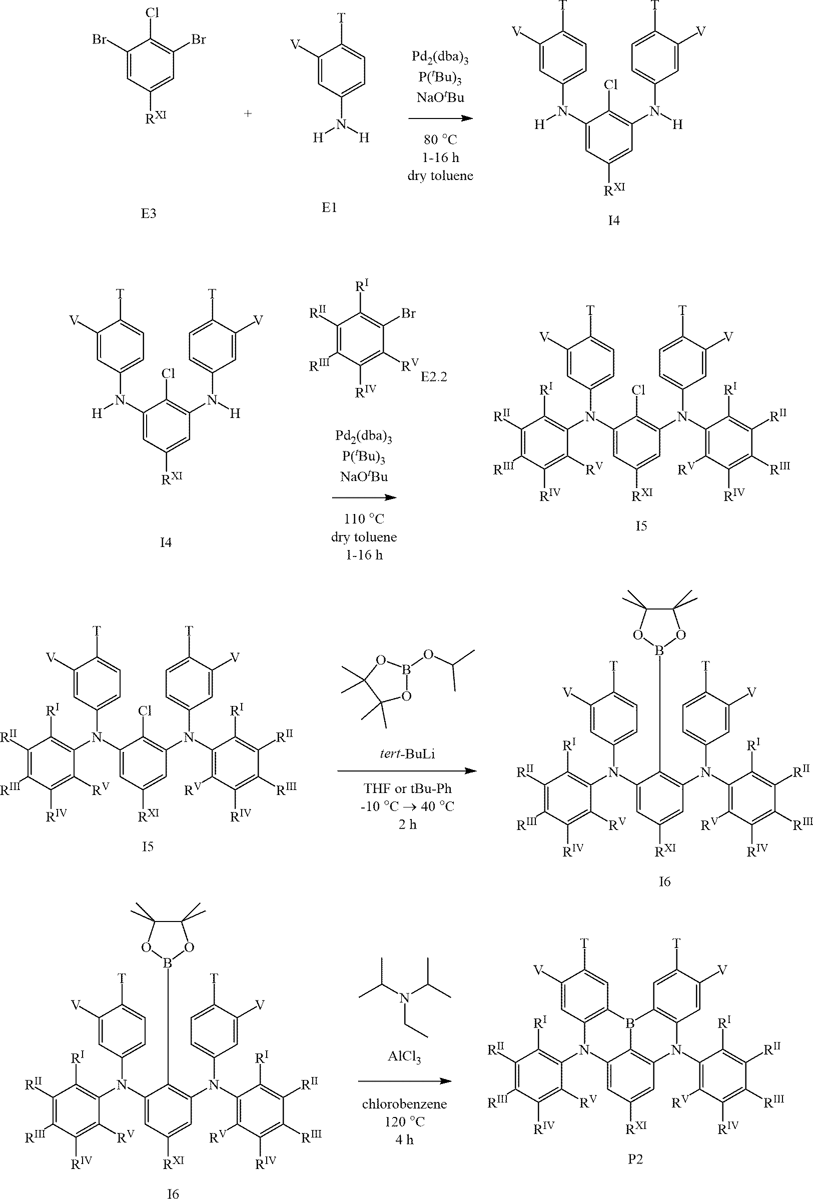

### Alternative One-Pot Procedure to Convert I5 Into P2

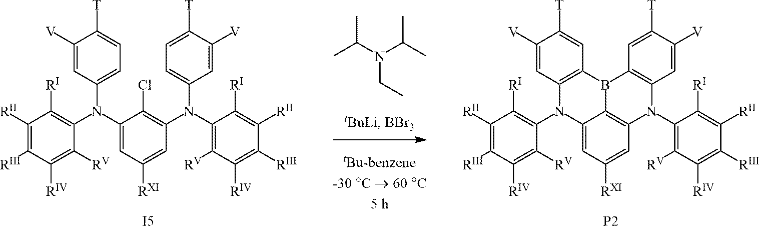

### General Procedure for Synthesis AAV6

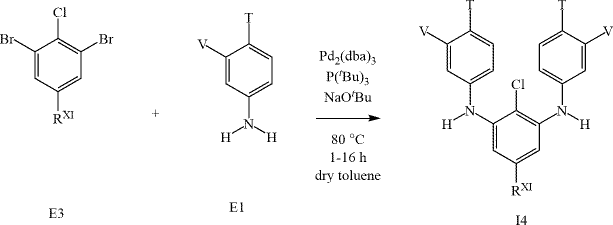

E3 (1.00 equivalents), E1 (2.20 equivalents), tris(dibenzylideneacetone)dipalladium Pd₂(dba)₃ (0.01 equivalents; CAS: 51364-51-3), tri-tert-butyl-phosphine (P(^{t}Bu)₃, CAS: 13716-12-6, 0.04 equivalents) and sodium tert-butoxide (NaO^{t}Bu; 3.30 equivalents) were stirred under nitrogen atmosphere in toluene at 80° C. for 1-16 h. After cooling down to room temperature (rt) the reaction mixture was extracted with toluene and water and the phases were separated. The combined organic layers were dried over MgSO₄ and then the solvent was removed under reduced pressure. The crude product obtained was purified by recrystallization or column chromatography and I4 was obtained as a solid or an oil.

### General Procedure for Synthesis AAV7

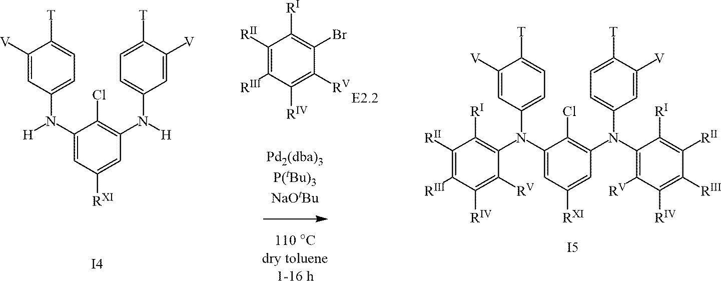

I4 (1.00 equivalents), E2.2 (2.20 equivalents), tris(dibenzylideneacetone)-dipalladium Pd₂(dba)₃ (0.02 equivalents; CAS: 51364-51-3), tri-tert-butyl-phosphine (0.08 equivalents, P(^{t}Bu)₃, CAS: 13716-12-6) and sodium tert-butoxide (NaO^{t}Bu; 3.30 equivalents) were stirred under nitrogen atmosphere in toluene at 110° C. for 1-16 h. After cooling down to room temperature (rt) the reaction mixture was extracted with toluene and water and the phases were separated. The combined organic layers were dried over MgSO₄ and then the solvent was removed under reduced pressure. The crude product obtained was purified by recrystallization or column chromatography and I5 was obtained as a solid.

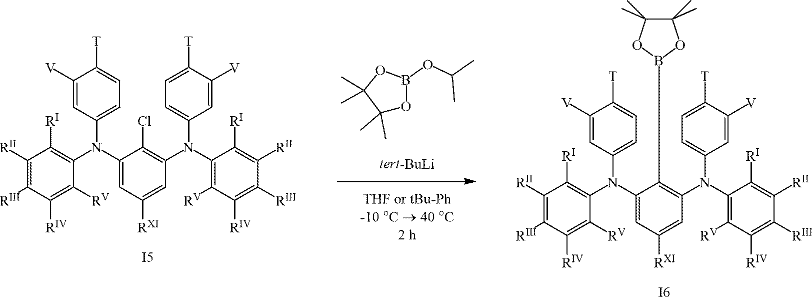

Boronic acid ester I6 was obtained according to AAV3 using compound I5 as the starting material. Alternatively, trimethyl borate may be used as borylating reagent yielding the boronic acid derivatives corresponding to I6.

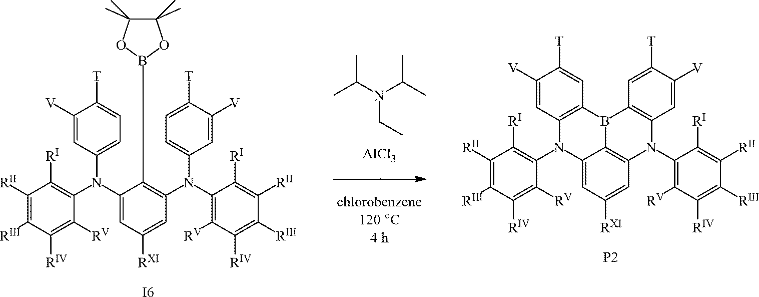

Target compound P2 was synthesized according to AAV4 using boronic acid ester I6 as the starting material. Alternatively, the boronic acid derivative corresponding to I6 can be used as the starting material for the synthesis of P2.

### Alternative One-Pot Procedure to Convert I5 Into P2

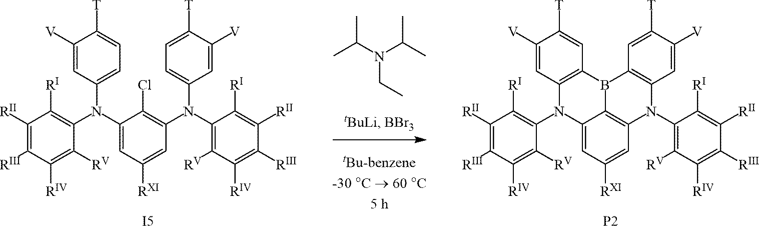

The synthesis of the target P2 was conducted via a one-pot protocol, where the chloride precursor I5 was directly converted into P2 following the procedure described within AAV5.

### General Synthesis Scheme III

General synthesis scheme III provides a synthesis scheme for organic molecules according to the invention where the limitations of scheme I and II (i.e. R^{X} = R^{I}, R^{IX} = R^{II}, R^{VIII} = R^{III}, R^{VII} = R^{IV}, and R^{V} = R^{VI}) do not apply.

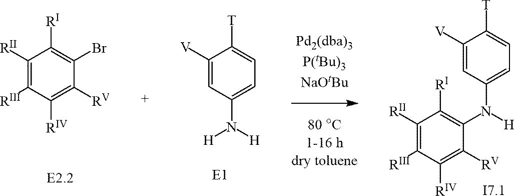

The synthesis of compound I7.1 was carried out following the procedure described under AAV1, using E2.2 (1.1 equivalents) and amine E1 as the reactants.

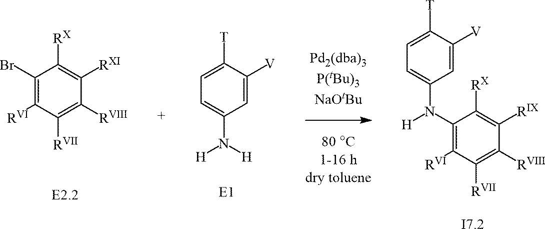

The synthesis of compound I7.2 was carried out following the procedure described under AAV1, using E2.2 (1.1 equivalents) and amine E1 as the reactants.

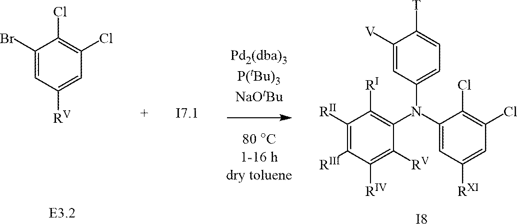

### Compound I8 Was Synthesized According to AAV8

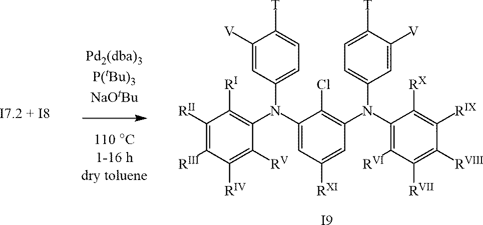

### Compound I9 Was Synthesized According to AAV9

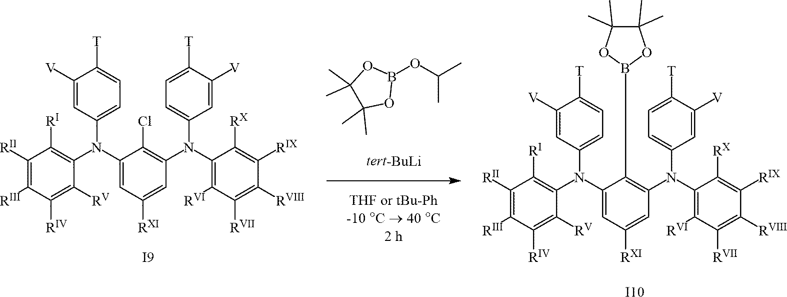

The synthesis of boronic acid ester I10 was carried out as described within AAV3 using precursor I9 as the substrate. Alternatively, trimethyl borate may be used as borylating reagent yielding the boronic acid derivatives corresponding to I10.

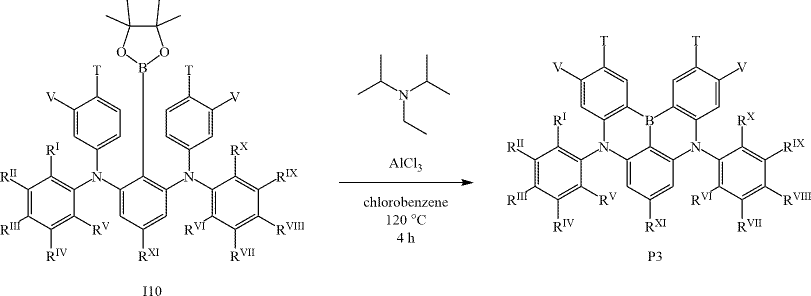

Target compound P3 was synthesized according to AAV4 using boronic acid ester I10 as the starting material. Alternatively, the boronic acid corresponding to I10 might be used as the starting material for the synthesis of P3.

### Alternative One-Pot Procedure to Convert I9 Into P3

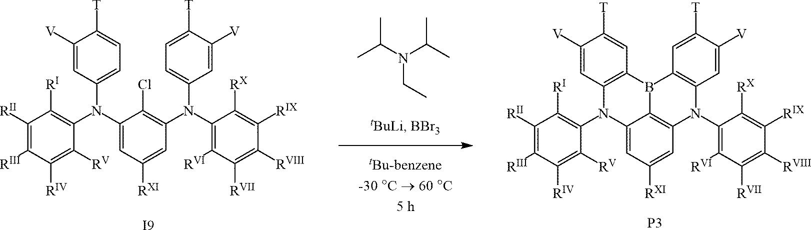

The synthesis of the target P3 was conducted via a one-pot protocol, where the chloride precursor I9 was directly converted into P3 following the procedure described within AAV5.

### General Procedure for Synthesis AAV8

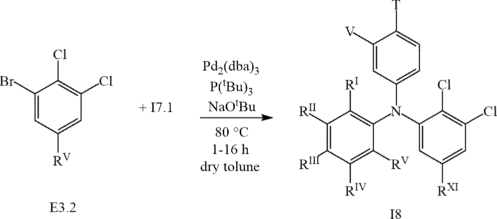

E3.2 (1.10 equivalents), I7.1 (1.00 equivalents), tris(dibenzylideneacetone)dipalladium Pd₂(dba)₃ (0.01 equivalents; CAS: 51364-51-3), tri-tert-butyl-phosphine (P(^{t}Bu)₃, CAS: 13716-12-6, 0.04 equivalents) and sodium tert-butoxide (NaO^{t}Bu; 1.70 equivalents) were stirred under nitrogen atmosphere in toluene at 80° C. for 5 h. After cooling down to room temperature (rt) the reaction mixture was extracted between toluene and brine and the phases were separated. The combined organic layers were dried over MgSO₄ and then the solvent was removed under reduced pressure. The crude product obtained was purified by recrystallization or column chromatography and I8 was obtained as a solid.

### General Procedure for Synthesis AAV9

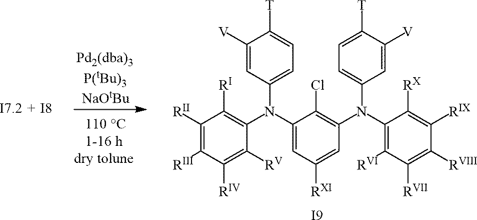

I7.2 (1.10 equivalents), I8 (1.00 equivalents), tris(dibenzylideneacetone)dipalladium Pd₂(dba)₃ (0.01 equivalents; CAS: 51364-51-3), tri-tert-butyl-phosphine (P(^{t}Bu)₃, CAS: 13716-12-6, 0.04 equivalents) and sodium tert-butoxide (NaO^{t}Bu; 1.70 equivalents) were stirred under nitrogen atmosphere in toluene at 110° C. for 5 h. After cooling down to room temperature (rt) the reaction mixture was extracted between toluene and brine and the phases were separated. The combined organic layers were dried over MgSOa and then the solvent was removed under reduced pressure. The crude product obtained was purified by recrystallization or column chromatography and I9 was obtained as a solid.

### General Synthesis Scheme IV

General synthesis scheme IV provides a synthesis scheme for organic molecules according to the invention, wherein R^{X} = R^{I}, R^{IX} = R^{II}, R^{VIII} = R^{III}, R^{VII} = R^{IV}, and R^{V} = R^{VI}:

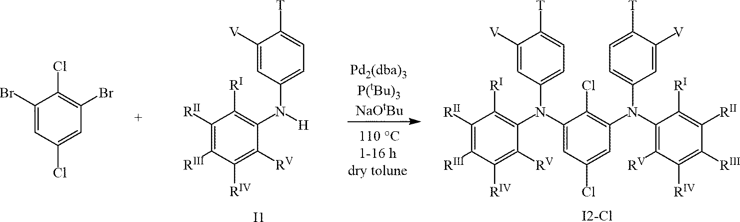

The synthesis of dichloro derivative I2-Cl was performed as described within AAV2, starting from 1,3-dibromo-2,5-dichlorobenzene (1.0 equivalents, CAS: 81067-41-6) and amine I1.

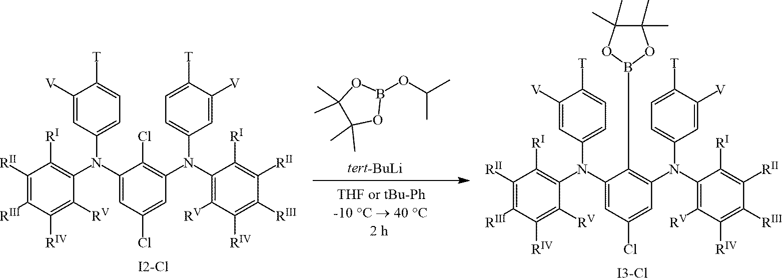

Boronic ester I3-Cl was synthesized from I2-CI following the procedure of AAV3, wherein alternatively, trimethyl borate may be used as borylating reagent yielding the boronic acid derivatives corresponding to I3-CI.

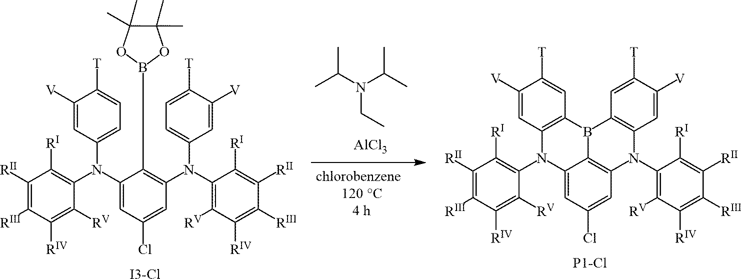

The para-chloro derivative P1-Cl was synthesized from I3-Cl as described within AAV4.

Alternatively, under the same conditions, the corresponding boronic acid derivative of substrate I3-Cl might be used as starting material yielding P1-Cl.

### Alternative One-Pot Ring Closure Scheme Directly Converting I2-CI to P1-Cl

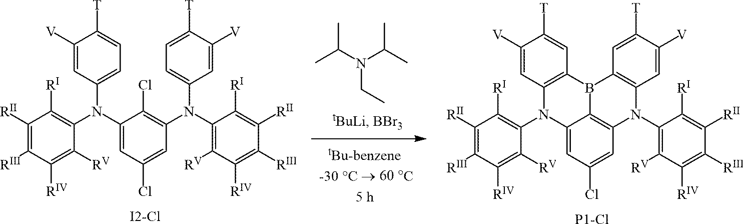

The one-pot synthesis of P1-Cl starting from I2-CI was carried out as described within AAV5.

### General Procedure for Synthesis AAV10

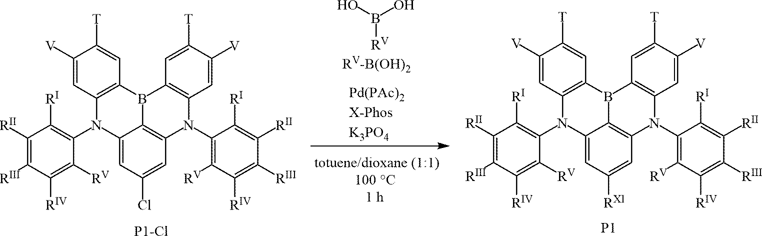

Under nitrogen atmosphere compound P1-Cl (1.0 equivalent), boronic acid R^{V}-B(OH)₂ (6.0 equivalents), Palladium-(II)-acetate (0.06 equivalents, CAS: 3375-31-3), X-Phos (0.24 equivalents, CAS: 564483-18-7) and tribasic potassium phosphate (9.0 equivalents, CAS: 7778-53-2) were stirred in a mixture of toluene and dioxane (1:1) at 100° C. for 1 h. After cooling down to room temperature (rt) the reaction mixture was extracted with toluene and water and the phases were separated. The combined organic layers were treated with activated charcoal for 10 min, followed by filtration through a pad of Celite® (kieselgur). The filtrate was dried over MgSO₄ and then the solvent was removed under reduced pressure. The crude product obtained was purified by recrystallization or column chromatography and P1 was obtained as a solid.

### General Synthesis Scheme V

General synthesis scheme V provides a synthesis scheme for organic molecules according to the invention, wherein R^{X} = R^{I}, R^{IX} = R^{II}, R^{VIII} = R^{III}, R^{VII} = R^{IV}, and R^{V} = R^{VI}:

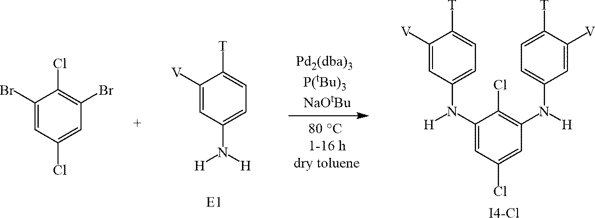

Compound I4-Cl was synthesized accordingly to procedure AAV6 where 1,3-dibromo-2,5-dichlorobenzene (1.0 equivalent, CAS 81067-41-6) and primary amine E1 were used as the reactants.

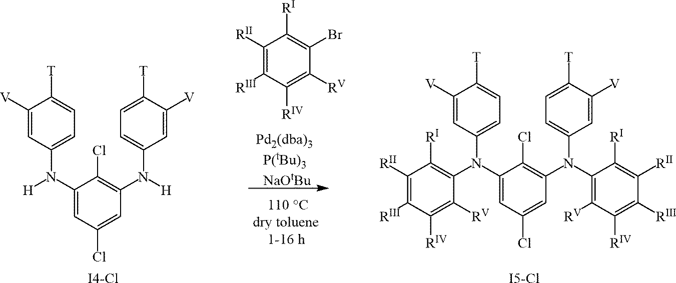

Compound I5-Cl was obtained by following the procedure AAV7 using secondary bisamine I4-Cl and 1-bromo-3,5-diphenylbenzene (CAS: 103068-20-8) as the reactants.

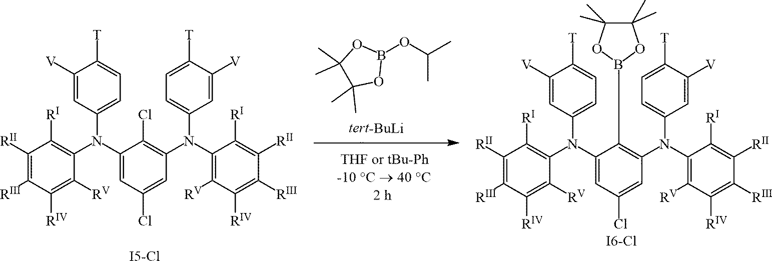

Boronic acid ester I6-Cl was obtained according to AAV3 using compound I5-Cl as the starting material. Alternatively, under the same conditions, trimethyl borate may be used as borylating reagent yielding the boronic acid derivatives corresponding to I6-Cl.

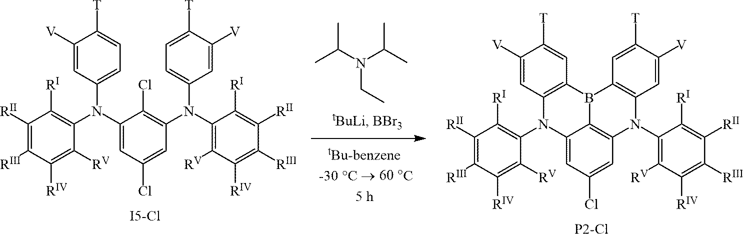

The synthesis of P2-Cl was conducted as described in AAV5 using I5-Cl as the substrate.

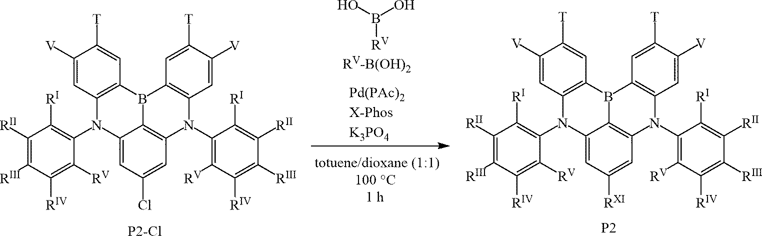

The target material P2 was synthesized as described in AAV10 using P2-Cl as the starting material.

### General Synthesis Scheme VI

General synthesis scheme VI provides a synthesis scheme for organic molecules according to the invention where the limitations of scheme I and II (i.e. R^{X} = R^{I}, R^{IX} = R^{II}, R^{VIII} = R^{III}, R^{VII} = R^{IV}, and R^{V} = R^{VI}) do not apply.

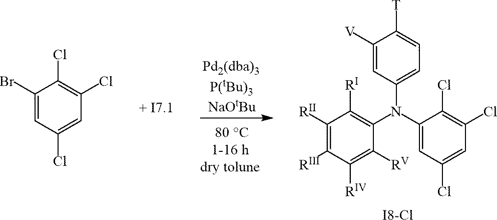

Compound I8-Cl was synthesized as described within AAV8, where 1-bromo-2,3,5-trichlorobenzene (1.0 equivalent) and amine 17.1 were used as the reactants.

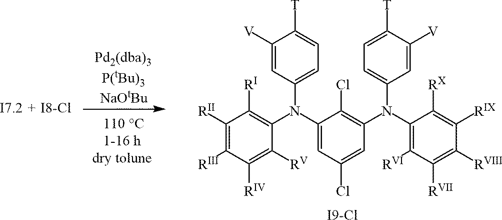

### Compound I9-Cl Was Synthesized From I7.2 and I8-Cl According to AAV9

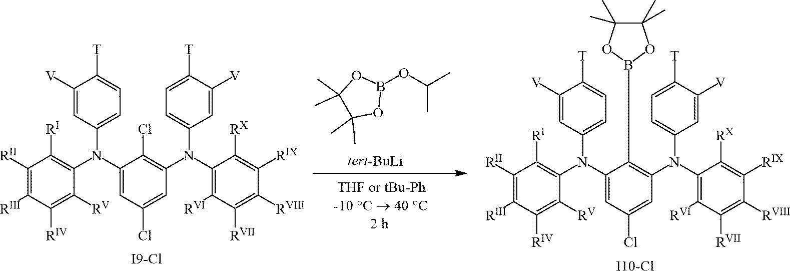

The synthesis of boronic acid ester I10-Cl was carried out as described within AAV3 using precursor I9-Cl as the substrate. Alternatively, trimethyl borate may be used as borylating reagent yielding the boronic acid derivatives corresponding to I10-Cl.

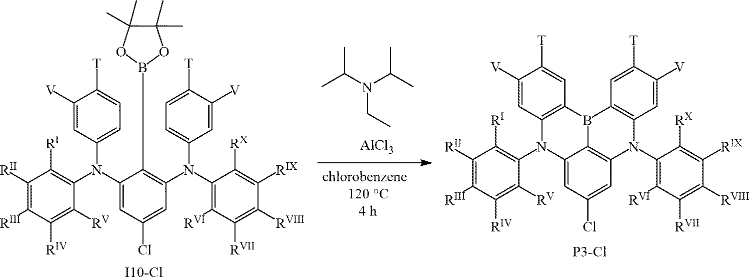

Compound P3-CI was synthesized according to AAV4 using boronic acid ester I10-Cl as the starting material. Alternatively, the boronic acid corresponding to I10-CI might be used as the starting material for the synthesis of P3-Cl.

### Alternative One-Pot Procedure to Convert I9-Cl Into P3-Cl

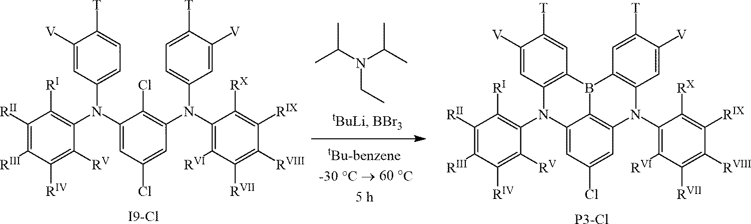

The synthesis of P3-CI was conducted as described in AAV5 using I9-Cl as the substrate.

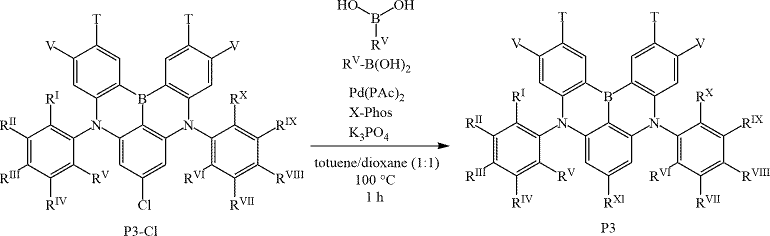

The target material P3 was synthesized as described in AAV10 using P3-CI as the starting material.

### Cyclic Voltammetry

Cyclic voltammograms were measured from solutions having concentration of 10⁻³ mol/L of the organic molecules in dichloromethane or a suitable solvent and a suitable supporting electrolyte (e.g. 0.1 mol/L of tetrabutylammonium hexafluorophosphate). The measurements were conducted at room temperature under nitrogen atmosphere with a three-electrode assembly (Working and counter electrodes: Pt wire, reference electrode: Pt wire) and calibrated using FeCp₂/FeCp₂⁺ as internal standard. The HOMO data was corrected using ferrocene as internal standard against a saturated calomel electrode (SCE).

### Density Functional Theory Calculation

Molecular structures were optimized employing the BP86 functional and the resolution of identity approach (RI). Excitation energies were calculated using the (BP86) optimized structures employing Time-Dependent DFT (TD-DFT) methods. Orbital and excited state energies were calculated with the B3LYP functional. Def2-SVP basis sets (and an m4-grid for numerical integration were used. The Turbomole program package was used for all calculations.

### Photophysical Measurements

### Sample Pretreatment: Spin-Coating

Apparatus: Spin150, SPS euro.

The sample concentration was 10 mg/ml, dissolved in a suitable solvent.
Program: 1) 3 s at 400 U/min; 2) 20 s at 1000 U/min at 1000 Upm/s. 3) 10 s at 4000 U/min at 1000 Upm/s. After coating, the films were dried at 70° C. for 1 min.
Photoluminescence spectroscopy and Time-Correlated Single-Photon Counting (TCSPC)

Steady-state emission spectroscopy was measured by a Horiba Scientific, Modell FluoroMax-4 equipped with a 150 W Xenon-Arc lamp, excitation- and emissions monochromators and a Hamamatsu R928 photomultiplier and a time-correlated single-photon counting option. Emissions and excitation spectra were corrected using standard correction fits.

Excited state lifetimes were determined employing the same system using the TCSPC method with FM-2013 equipment and a Horiba Yvon TCSPC hub.

### Excitation Sources

NanoLED 370 (wavelength: 371 nm, puls duration: 1,1 ns)
NanoLED 290 (wavelength: 294 nm, puls duration: <1 ns)
SpectraLED 310 (wavelength: 314 nm)
SpectraLED 355 (wavelength: 355 nm).

Data analysis (exponential fit) was done using the software suite DataStation and DAS6 analysis software. The fit was specified using the chi-squared-test.

### Photoluminescence Quantum Yield Measurements

For photoluminescence quantum yield (PLQY) measurements an Absolute PL Quantum Yield Measurement C9920-03G system (Hamamatsu Photonics) was used. Quantum yields and CIE coordinates were determined using the software U6039-05 version 3.6.0.

Emission maxima were given in nm, quantum yields Φ in % and CIE coordinates as x,y values.

### PLQY Was Determined Using the Following Protocol

Quality assurance: Anthracene in ethanol (known concentration) was used as reference

Excitation wavelength: the absorption maximum of the organic molecule was determined and the molecule was excited using this wavelength

### Measurement

Quantum yields were measured, for sample, of solutions or films under nitrogen atmosphere. The yield was calculated using the equation:

$$\begin{matrix}{\text{Φ}}_{P L} = \frac{{n}_{p h o t o n} , e m i t e d}{{n}_{p h o t o n} , a b s o r b e d} = \\ \frac{\int \frac{λ}{h c} \left[I n {t}_{e m i t t e d}^{s a m p l e} \left(λ\right) - I n {t}_{a b s o r b e d}^{s a m p l e} \left(λ\right)\right] d λ}{\int \frac{λ}{h c} \left[I n {t}_{e m i t t e d}^{r e f e r e n c e} \left(λ\right) - I n {t}_{a b s o r b e d}^{r e f e r e n c e} \left(λ\right)\right] d λ}\end{matrix}$$

wherein nₚₕₒₜₒₙ denotes the photon count and Int. denotes the intensity.

### Production and Characterization of Optoelectronic Devices

Optoelectronic devices, in particular OLED devices, including organic molecules according to the invention can be produced via vacuum-deposition methods. If a layer contains more than one compound, the weight-percentage of one or more compounds was given in %. The total weight-percentage values amount to 100%, thus if a value was not given, the fraction of this compound equals to the difference between the given values and 100%.

The not fully optimized OLEDs were characterized using standard methods and measuring electroluminescence spectra, the external quantum efficiency (in %) in dependency on the intensity, calculated using the light detected by the photodiode, and the current. The OLED device lifetime was extracted from the change of the luminance during operation at constant current density. The LT50 value corresponds to the time, where the measured luminance decreased to 50% of the initial luminance, analogously LT80 corresponds to the time point, at which the measured luminance decreased to 80% of the initial luminance, LT 95 to the time point, at which the measured luminance decreased to 95% of the initial luminance etc.

Accelerated lifetime measurements were performed (e.g. applying increased current densities). For example, LT80 values at 500 cd/m² were determined using the following equation:

$$\text{LT} 80 \left(500 \frac{c {d}^{2}}{{m}^{2}}\right) = \text{LT} 80 \left({L}_{0}\right) {\left(\frac{{L}_{0}}{500 \frac{c {d}^{2}}{{m}^{2}}}\right)}^{1.6}$$

wherein L₀ denotes the initial luminance at the applied current density.

The values correspond to the average of several pixels (typically two to eight), the standard deviation between these pixels was given.

### HPLC-MS

HPLC-MS analysis was performed on an HPLC by Agilent (1100 series) with MS-detector (Thermo LTQ XL).

Exemplarily a typical HPLC method was as follows: a reverse phase column 4.6 mm × 150 mm, particle size 3.5 µm from Agilent (ZORBAX Eclipse Plus 95 Å C18, 4.6 × 150 mm, 3.5 µm HPLC column) was used in the HPLC. The HPLC-MS measurements were performed at room temperature (rt) with the following gradients

| Flow rate [ml/min] | Time [min] | A[%] | B[%] | C[%] |
|---|---|---|---|---|
| 2.5 | 0 | 40 | 50 | 10 |
| 2.5 | 5 | 40 | 50 | 10 |
| 2.5 | 25 | 10 | 20 | 70 |
| 2.5 | 35 | 10 | 20 | 70 |
| 2.5 | 35.01 | 40 | 50 | 10 |
| 2.5 | 40.01 | 40 | 50 | 10 |
| 2.5 | 41.01 | 40 | 50 | 10 |

using the following solvent mixtures:

| | | |
|---|---|---|
| Solvent A: | H2O (90%) | MeCN (10%) |
| Solvent B: | H2O (10%) | MeCN (90%) |
| Solvent C: | THF (50%) | MeCN (50%) |

An injection volume of 5 µL from a solution with a concentration of 0.5 mg/mL of the analyte was taken for the measurements.

Ionization of the probe was performed using an atmospheric pressure chemical ionization (APCI) source either in positive (APCI +) or negative (APCI -) ionization mode.

### Example 1

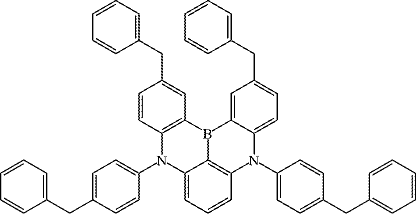 [SMILES: c1ccc(Cc2ccc(N3c4ccc(Cc5ccccc5)cc4B4c5cc(Cc6ccccc6)ccc5N(c5ccc(Cc6ccccc6)cc5)c5cccc3c54)cc2)cc1]

Example 1 was synthesized according to
AA V1 (49% yield), wherein 4-chlorodiphenylmethane (CAS 831-81-2) was used as reactant E2 and 4-benzylaniline (CAS 1135-12-2) as E1;
AA V2 (42% yield), wherein 1,3-dibromo-2-chlorobenzene (CAS 19230-27-4) was used as reactant E3;
and AA V5 (48% yield).

MS (HPLC-MS, APCI, pos. ionization), m/z (retention time): 781.6 (6.16 min).

The emission maximum of example 1 (2% by weight in PMMA) was at 464 nm, the full width at half maximum (FWHM) was 0.17 eV, the CIEy coordinate was 0.12 and the PLQY was 73%. The onset of the emission spectrum was determined at 2.79 eV.

### Example 2

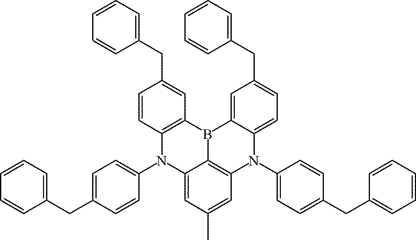 [SMILES: Cc1cc2c3c(c1)N(c1ccc(Cc4ccccc4)cc1)c1ccc(Cc4ccccc4)cc1B3c1cc(Cc3ccccc3)ccc1N2c1ccc(Cc2ccccc2)cc1]

Example 2 was synthesized according to
AA V1 (49% yield), wherein 4-chlorodiphenylmethane (CAS 831-81-2) was used as reactant E2 and 4-benzylaniline (CAS 1135-12-2) as E1;
AA V2 (69% yield), wherein 4-chloro-3,5-dibromotoluene (CAS 202925-05-1) was used as reactant E3;
and AAV5 (13% yield).

MS (HPLC-MS, APPI, pos. ionization), m/z (retention time): 795.6 (6.26 min).

The emission maximum of example 2 (2% by weight in PMMA) was at 462 nm, the full width at half maximum (FWHM) was 0.17 eV, the CIEy coordinate was 0.11 and the PLQY was 76%. The onset of the emission spectrum was determined at 2.79 eV.

### Example 3

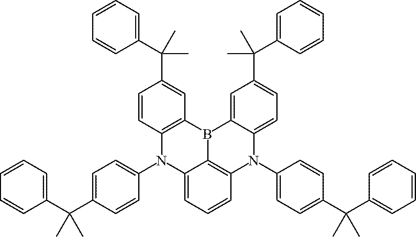 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cccc2c43)cc1]

Example 3 was synthesized according to
AAV2 (83% yield), wherein 1,3-dibromo-2-chlorobenzene (CAS 19230-27-4) and 4,4′-bis(alpha,alpha-dimethylbenzyl)diphenylamine (CAS 10081-67-1) were used as reactants E3 and I1, respectively;
AAV3 (32% yield), wherein trimethyl borate (CAS 121-43-7) was used as the borylating reagent and wherein the corresponding boronic acid derivative of I3 was obtained;
and AA V4 (23% yield).

MS (HPLC-MS, APPI, pos. ionization), m/z (retention time): 893.7 (7.66 min).

The emission maximum of example 3 (2% by weight in PMMA) was at 462 nm, the full width at half maximum (FWHM) was 0.16 eV, the CIEy coordinate was 0.10 and the PLQY was 80%. The onset of the emission spectrum was determined at 2.79 eV.

### Example 4

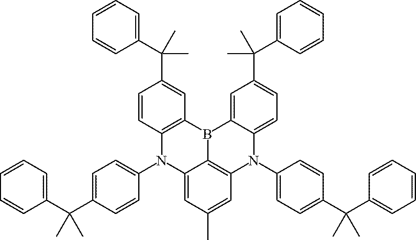 [SMILES: Cc1cc2c3c(c1)N(c1ccc(C(C)(C)c4ccccc4)cc1)c1ccc(C(C)(C)c4ccccc4)cc1B3c1cc(C(C)(C)c3ccccc3)ccc1N2c1ccc(C(C)(C)c2ccccc2)cc1]

Example 4 was synthesized according to
AA V2 (72% yield), wherein 4-chloro-3,5-dibromotoluene (CAS 202925-05-1) and 4,4′-bis(alpha,alpha-dimethylbenzyl)diphenylamine (CAS 10081-67-1) were used as reactants E3 and I1, respectively;
AAV3 (50% yield), wherein trimethyl borate (CAS 121-43-7) was used as the borylating reagent and wherein the corresponding dichloride I2-CI was used as the reactant and wherein the corresponding boronic acid derivative of I3-CI was obtained;
AAV4 (58% yield);
and AAV10 (81% yield), wherein the corresponding starting material P1-CI was reacted with methaneboronic acid (CAS: 13061-96-6).

MS (HPLC-MS), m/z (retention time): 907.80 (7.68 min).

The emission maximum of example 4 (2% by weight in PMMA) was at 461 nm, the full width at half maximum (FWHM) was 0.17 eV, the CIEy coordinate was 0.10 and the PLQY was 81%. The onset of the emission spectrum was determined at 2.81 eV.

### Example D1

Example 1 was tested in the OLED D1, which was fabricated with the following layer structure:

| | | |
|---|---|---|
| Layer # | Thickness | D1 |
| 9 | 100 nm | Al |
| 8 | 2 nm | Liq |
| 7 | 11 nm | NBPhen |
| 6 | 20 nm | MAT1 |
| 5 | 20 nm | MAT2 (98%) : Example 1 (2%) |
| 4 | 10 nm | MAT3 |
| 3 | 50 nm | MAT4 |
| 2 | 7 nm | HAT-CN |
| 1 | 50 nm | ITO |
| Substrate | | Glass |

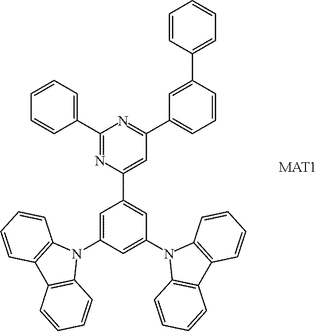 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

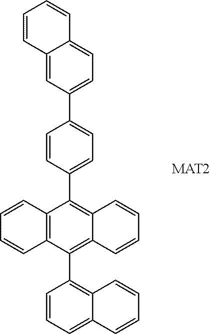 [SMILES: c1ccc2cc(-c3ccc(-c4c5ccccc5c(-c5cccc6ccccc56)c5ccccc45)cc3)ccc2c1]

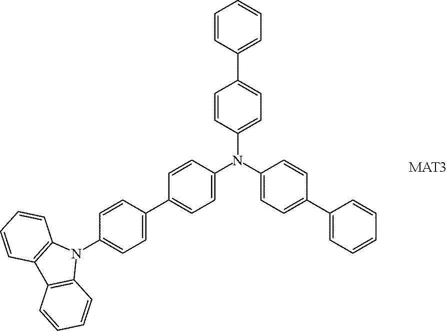 [SMILES: c1ccc(-c2ccc(N(c3ccc(-c4ccccc4)cc3)c3ccc(-c4ccc(-n5c6ccccc6c6ccccc65)cc4)cc3)cc2)cc1]

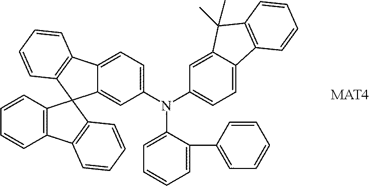 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

OLED D1 yielded an external quantum efficiency (EQE) at 1000 cd/m² of 12.1 %. The emission maximum was at 468 nm with a FWHM of 26 nm at 3.6 V. The corresponding CIEy value was 0.12.

### Example D2

Example 2 was tested in the OLED D2, which was fabricated with the following layer structure:

| | | |
|---|---|---|
| Layer # | Thickness | D2 |
| 9 | 100 nm | Al |
| 8 | 2 nm | Liq |
| 7 | 11 nm | NBPhen |
| 6 | 20 nm | MAT1 |
| 5 | 20 nm | MAT2 (98%) : Example 2 (2%) |
| 4 | 10 nm | MAT3 |
| 3 | 50 nm | MAT4 |
| 2 | 7 nm | HAT-CN |
| 1 | 50 nm | ITO |
| Substrate | | Glass |

OLED D2 yielded an external quantum efficiency (EQE) at 1000 cd/m² of 10.9%. The emission maximum was at 464 nm with a FWHM of 28 nm at 3.8 V. The corresponding CIEy value was 0.10.

### Example D3

Example 3 was tested in the OLED D3, which was fabricated with the following layer structure:

| | | |
|---|---|---|
| Layer # | Thickness | D3 |
| 9 | 100 nm | Al |
| 8 | 2 nm | Liq |
| 7 | 11 nm | NBPhen |
| 6 | 20 nm | MAT1 |
| 5 | 20 nm | MAT2 (98%) : Example 3 (2%) |
| 4 | 10 nm | MAT3 |
| 3 | 50 nm | MAT4 |
| 2 | 7 nm | HAT-CN |
| 1 | 50 nm | ITO |
| Substrate | | Glass |

OLED D3 yielded an external quantum efficiency (EQE) at 1000 cd/m² of 11.8%. The emission maximum was at 466 nm with a FWHM of 26 nm at 3.5 V. The corresponding CIEy value was 0.10.

### Example D4

Example 4 was tested in the OLED D4, which was fabricated with the following layer structure:

| | | |
|---|---|---|
| Layer # | Thickness | D4 |
| 9 | 100 nm | Al |
| 8 | 2 nm | Liq |
| 7 | 11 nm | NBPhen |
| 6 | 20 nm | MAT1 |
| 5 | 20 nm | MAT2 (98%) : Example 4 (2%) |
| 4 | 10 nm | MAT3 |
| 3 | 50 nm | MAT4 |
| 2 | 7 nm | HAT-CN |
| 1 | 50 nm | ITO |
| Substrate | | Glass |

OLED D4 yielded an external quantum efficiency (EQE) at 1000 cd/m² of 11.2%. The emission maximum was at 464 nm with a FWHM of 26 nm at 3.6 V. The corresponding CIEy value was 0.09.

Additional Examples of Organic Molecules of the Invention

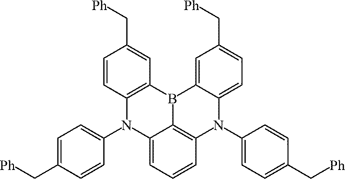 [SMILES: c1ccc(Cc2ccc(N3c4ccc(Cc5ccccc5)cc4B4c5cc(Cc6ccccc6)ccc5N(c5ccc(Cc6ccccc6)cc5)c5cccc3c54)cc2)cc1]

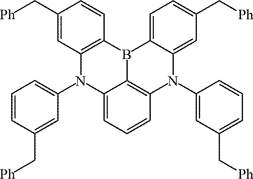 [SMILES: c1ccc(Cc2cccc(N3c4cc(Cc5ccccc5)ccc4B4c5ccc(Cc6ccccc6)cc5N(c5cccc(Cc6ccccc6)c5)c5cccc3c54)c2)cc1]

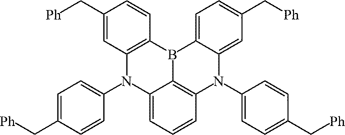 [SMILES: c1ccc(Cc2ccc(N3c4cc(Cc5ccccc5)ccc4B4c5ccc(Cc6ccccc6)cc5N(c5ccc(Cc6ccccc6)cc5)c5cccc3c54)cc2)cc1]

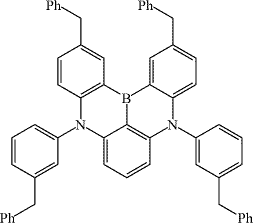 [SMILES: c1ccc(Cc2cccc(N3c4ccc(Cc5ccccc5)cc4B4c5cc(Cc6ccccc6)ccc5N(c5cccc(Cc6ccccc6)c5)c5cccc3c54)c2)cc1]

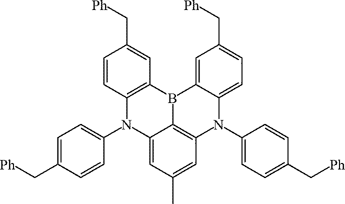 [SMILES: Cc1cc2c3c(c1)N(c1ccc(Cc4ccccc4)cc1)c1ccc(Cc4ccccc4)cc1B3c1cc(Cc3ccccc3)ccc1N2c1ccc(Cc2ccccc2)cc1]

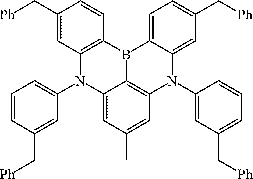 [SMILES: Cc1cc2c3c(c1)N(c1cccc(Cc4ccccc4)c1)c1cc(Cc4ccccc4)ccc1B3c1ccc(Cc3ccccc3)cc1N2c1cccc(Cc2ccccc2)c1]

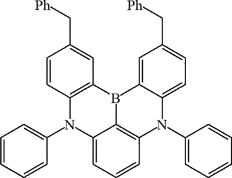 [SMILES: c1ccc(Cc2ccc3c(c2)B2c4cc(Cc5ccccc5)ccc4N(c4ccccc4)c4cccc(c42)N3c2ccccc2)cc1]

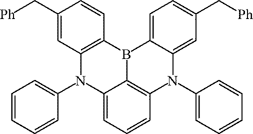 [SMILES: c1ccc(Cc2ccc3c(c2)N(c2ccccc2)c2cccc4c2B3c2ccc(Cc3ccccc3)cc2N4c2ccccc2)cc1]

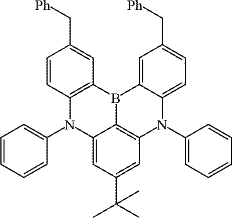 [SMILES: CC(C)(C)c1cc2c3c(c1)N(c1ccccc1)c1ccc(Cc4ccccc4)cc1B3c1cc(Cc3ccccc3)ccc1N2c1ccccc1]

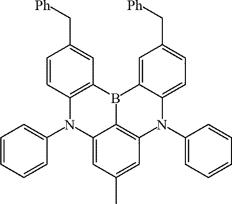 [SMILES: Cc1cc2c3c(c1)N(c1ccccc1)c1ccc(Cc4ccccc4)cc1B3c1cc(Cc3ccccc3)ccc1N2c1ccccc1]

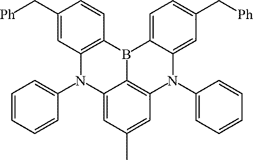 [SMILES: Cc1cc2c3c(c1)N(c1ccccc1)c1cc(Cc4ccccc4)ccc1B3c1ccc(Cc3ccccc3)cc1N2c1ccccc1]

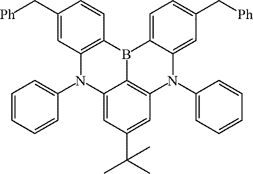 [SMILES: CC(C)(C)c1cc2c3c(c1)N(c1ccccc1)c1cc(Cc4ccccc4)ccc1B3c1ccc(Cc3ccccc3)cc1N2c1ccccc1]

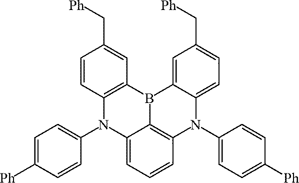 [SMILES: c1ccc(Cc2ccc3c(c2)B2c4cc(Cc5ccccc5)ccc4N(c4ccc(-c5ccccc5)cc4)c4cccc(c42)N3c2ccc(-c3ccccc3)cc2)cc1]

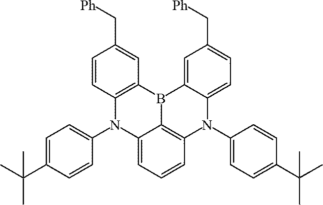 [SMILES: CC(C)(C)c1ccc(N2c3ccc(Cc4ccccc4)cc3B3c4cc(Cc5ccccc5)ccc4N(c4ccc(C(C)(C)C)cc4)c4cccc2c43)cc1]

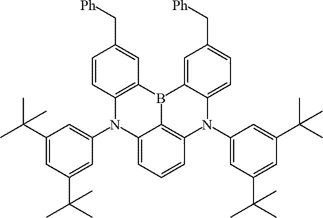 [SMILES: CC(C)(C)c1cc(N2c3ccc(Cc4ccccc4)cc3B3c4cc(Cc5ccccc5)ccc4N(c4cc(C(C)(C)C)cc(C(C)(C)C)c4)c4cccc2c43)cc(C(C)(C)C)c1]

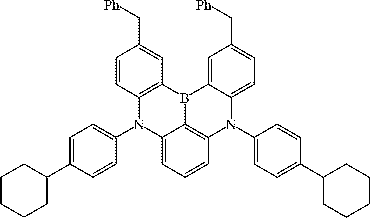 [SMILES: c1ccc(Cc2ccc3c(c2)B2c4cc(Cc5ccccc5)ccc4N(c4ccc(C5CCCCC5)cc4)c4cccc(c42)N3c2ccc(C3CCCCC3)cc2)cc1]

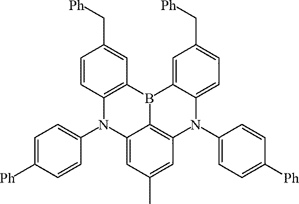 [SMILES: Cc1cc2c3c(c1)N(c1ccc(-c4ccccc4)cc1)c1ccc(Cc4ccccc4)cc1B3c1cc(Cc3ccccc3)ccc1N2c1ccc(-c2ccccc2)cc1]

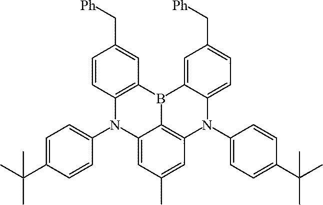 [SMILES: Cc1cc2c3c(c1)N(c1ccc(C(C)(C)C)cc1)c1ccc(Cc4ccccc4)cc1B3c1cc(Cc3ccccc3)ccc1N2c1ccc(C(C)(C)C)cc1]

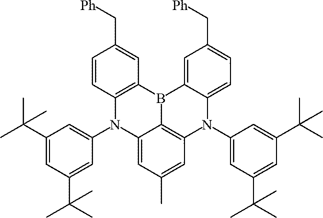 [SMILES: Cc1cc2c3c(c1)N(c1cc(C(C)(C)C)cc(C(C)(C)C)c1)c1ccc(Cc4ccccc4)cc1B3c1cc(Cc3ccccc3)ccc1N2c1cc(C(C)(C)C)cc(C(C)(C)C)c1]

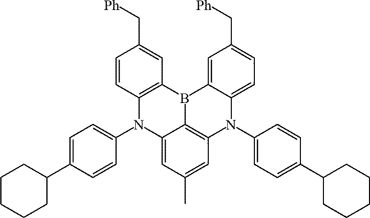 [SMILES: Cc1cc2c3c(c1)N(c1ccc(C4CCCCC4)cc1)c1ccc(Cc4ccccc4)cc1B3c1cc(Cc3ccccc3)ccc1N2c1ccc(C2CCCCC2)cc1]

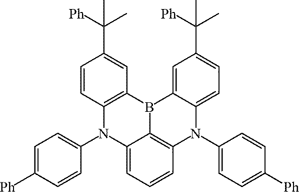 [SMILES: CC(C)(c1ccccc1)c1ccc2c(c1)B1c3cc(C(C)(C)c4ccccc4)ccc3N(c3ccc(-c4ccccc4)cc3)c3cccc(c31)N2c1ccc(-c2ccccc2)cc1]

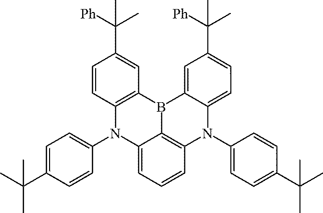 [SMILES: CC(C)(C)c1ccc(N2c3ccc(C(C)(C)c4ccccc4)cc3B3c4cc(C(C)(C)c5ccccc5)ccc4N(c4ccc(C(C)(C)C)cc4)c4cccc2c43)cc1]

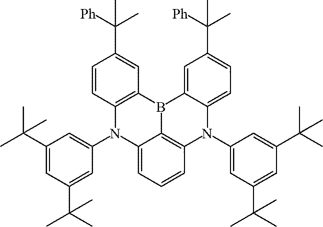 [SMILES: CC(C)(C)c1cc(N2c3ccc(C(C)(C)c4ccccc4)cc3B3c4cc(C(C)(C)c5ccccc5)ccc4N(c4cc(C(C)(C)C)cc(C(C)(C)C)c4)c4cccc2c43)cc(C(C)(C)C)c1]

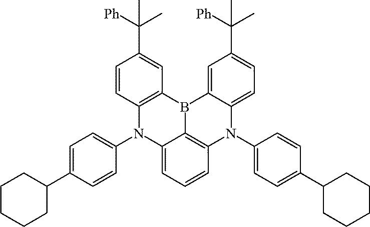 [SMILES: CC(C)(c1ccccc1)c1ccc2c(c1)B1c3cc(C(C)(C)c4ccccc4)ccc3N(c3ccc(C4CCCCC4)cc3)c3cccc(c31)N2c1ccc(C2CCCCC2)cc1]

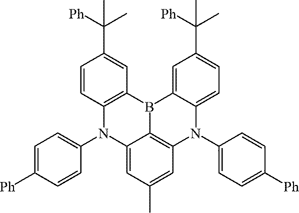 [SMILES: Cc1cc2c3c(c1)N(c1ccc(-c4ccccc4)cc1)c1ccc(C(C)(C)c4ccccc4)cc1B3c1cc(C(C)(C)c3ccccc3)ccc1N2c1ccc(-c2ccccc2)cc1]

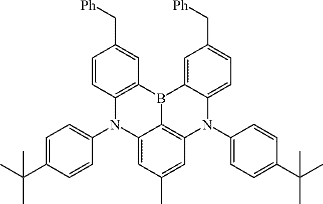 [SMILES: Cc1cc2c3c(c1)N(c1ccc(C(C)(C)C)cc1)c1ccc(Cc4ccccc4)cc1B3c1cc(Cc3ccccc3)ccc1N2c1ccc(C(C)(C)C)cc1]

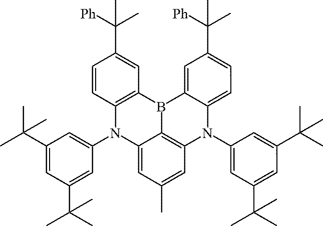 [SMILES: Cc1cc2c3c(c1)N(c1cc(C(C)(C)C)cc(C(C)(C)C)c1)c1ccc(C(C)(C)c4ccccc4)cc1B3c1cc(C(C)(C)c3ccccc3)ccc1N2c1cc(C(C)(C)C)cc(C(C)(C)C)c1]

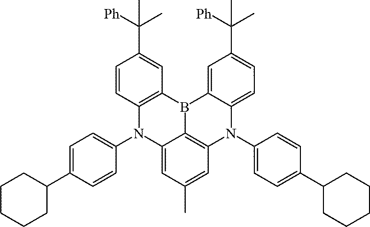 [SMILES: Cc1cc2c3c(c1)N(c1ccc(C4CCCCC4)cc1)c1ccc(C(C)(C)c4ccccc4)cc1B3c1cc(C(C)(C)c3ccccc3)ccc1N2c1ccc(C2CCCCC2)cc1]

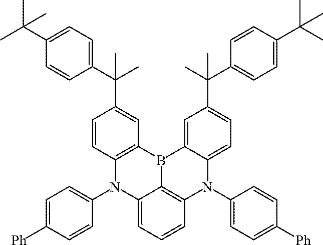 [SMILES: CC(C)(C)c1ccc(C(C)(C)c2ccc3c(c2)B2c4cc(C(C)(C)c5ccc(C(C)(C)C)cc5)ccc4N(c4ccc(-c5ccccc5)cc4)c4cccc(c42)N3c2ccc(-c3ccccc3)cc2)cc1]

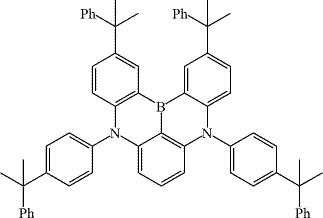 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cccc2c43)cc1]

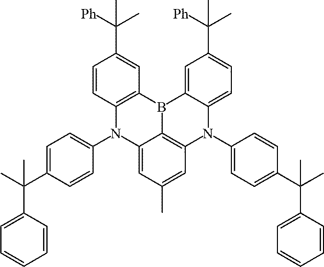 [SMILES: Cc1cc2c3c(c1)N(c1ccc(C(C)(C)c4ccccc4)cc1)c1ccc(C(C)(C)c4ccccc4)cc1B3c1cc(C(C)(C)c3ccccc3)ccc1N2c1ccc(C(C)(C)c2ccccc2)cc1]

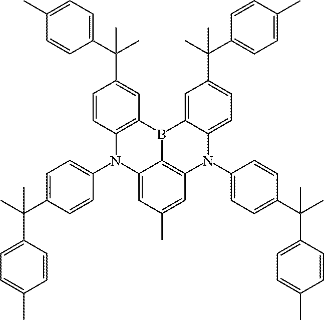 [SMILES: Cc1ccc(C(C)(C)c2ccc(N3c4ccc(C(C)(C)c5ccc(C)cc5)cc4B4c5cc(C(C)(C)c6ccc(C)cc6)ccc5N(c5ccc(C(C)(C)c6ccc(C)cc6)cc5)c5cc(C)cc3c54)cc2)cc1]

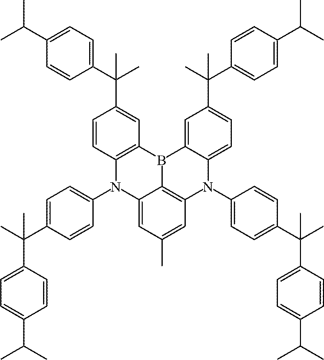 [SMILES: Cc1cc2c3c(c1)N(c1ccc(C(C)(C)c4ccc(C(C)C)cc4)cc1)c1ccc(C(C)(C)c4ccc(C(C)C)cc4)cc1B3c1cc(C(C)(C)c3ccc(C(C)C)cc3)ccc1N2c1ccc(C(C)(C)c2ccc(C(C)C)cc2)cc1]

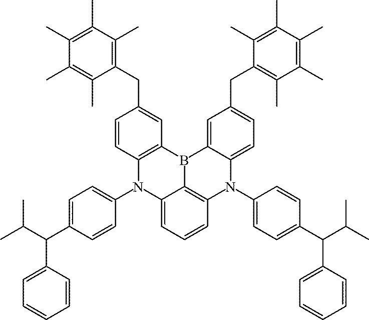 [SMILES: Cc1c(C)c(C)c(Cc2ccc3c(c2)B2c4cc(Cc5c(C)c(C)c(C)c(C)c5C)ccc4N(c4ccc(C(c5ccccc5)C(C)C)cc4)c4cccc(c42)N3c2ccc(C(c3ccccc3)C(C)C)cc2)c(C)c1C]

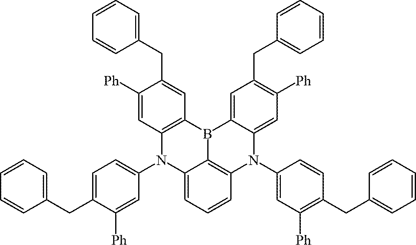 [SMILES: c1ccc(Cc2ccc(N3c4cc(-c5ccccc5)c(Cc5ccccc5)cc4B4c5cc(Cc6ccccc6)c(-c6ccccc6)cc5N(c5ccc(Cc6ccccc6)c(-c6ccccc6)c5)c5cccc3c54)cc2-c2ccccc2)cc1]

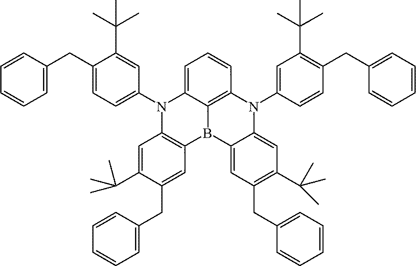 [SMILES: CC(C)(C)c1cc(N2c3cc(C(C)(C)C)c(Cc4ccccc4)cc3B3c4cc(Cc5ccccc5)c(C(C)(C)C)cc4N(c4ccc(Cc5ccccc5)c(C(C)(C)C)c4)c4cccc2c43)ccc1Cc1ccccc1]

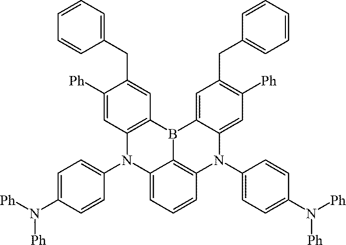 [SMILES: c1ccc(Cc2cc3c(cc2-c2ccccc2)N(c2ccc(N(c4ccccc4)c4ccccc4)cc2)c2cccc4c2B3c2cc(Cc3ccccc3)c(-c3ccccc3)cc2N4c2ccc(N(c3ccccc3)c3ccccc3)cc2)cc1]

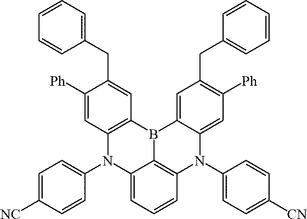

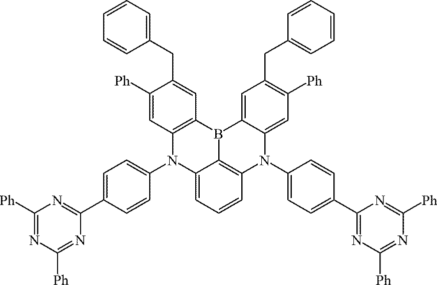 [SMILES: c1ccc(Cc2cc3c(cc2-c2ccccc2)N(c2ccc(-c4nc(-c5ccccc5)nc(-c5ccccc5)n4)cc2)c2cccc4c2B3c2cc(Cc3ccccc3)c(-c3ccccc3)cc2N4c2ccc(-c3nc(-c4ccccc4)nc(-c4ccccc4)n3)cc2)cc1]

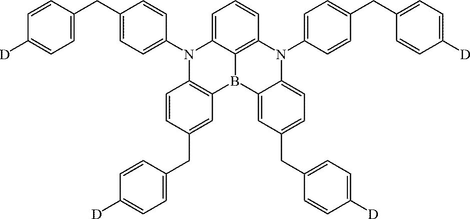 [SMILES: [2H]c1ccc(Cc2ccc(N3c4ccc(Cc5ccc([2H])cc5)cc4B4c5cc(Cc6ccc([2H])cc6)ccc5N(c5ccc(Cc6ccc([2H])cc6)cc5)c5cccc3c54)cc2)cc1]

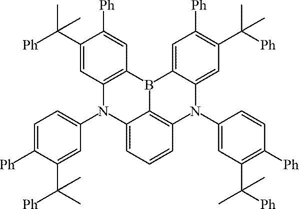 [SMILES: CC(C)(c1ccccc1)c1cc(N2c3cc(C(C)(C)c4ccccc4)c(-c4ccccc4)cc3B3c4cc(-c5ccccc5)c(C(C)(C)c5ccccc5)cc4N(c4ccc(-c5ccccc5)c(C(C)(C)c5ccccc5)c4)c4cccc2c43)ccc1-c1ccccc1]

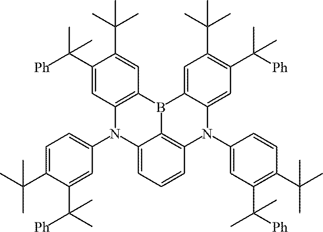 [SMILES: CC(C)(C)c1ccc(N2c3cc(C(C)(C)c4ccccc4)c(C(C)(C)C)cc3B3c4cc(C(C)(C)C)c(C(C)(C)c5ccccc5)cc4N(c4ccc(C(C)(C)C)c(C(C)(C)c5ccccc5)c4)c4cccc2c43)cc1C(C)(C)c1ccccc1]

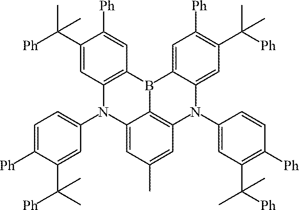 [SMILES: Cc1cc2c3c(c1)N(c1ccc(-c4ccccc4)c(C(C)(C)c4ccccc4)c1)c1cc(C(C)(C)c4ccccc4)c(-c4ccccc4)cc1B3c1cc(-c3ccccc3)c(C(C)(C)c3ccccc3)cc1N2c1ccc(-c2ccccc2)c(C(C)(C)c2ccccc2)c1]

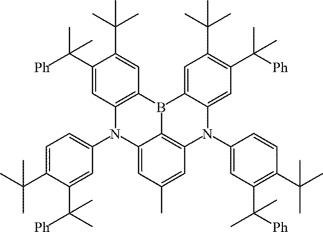 [SMILES: Cc1cc2c3c(c1)N(c1ccc(C(C)(C)C)c(C(C)(C)c4ccccc4)c1)c1cc(C(C)(C)c4ccccc4)c(C(C)(C)C)cc1B3c1cc(C(C)(C)C)c(C(C)(C)c3ccccc3)cc1N2c1ccc(C(C)(C)C)c(C(C)(C)c2ccccc2)c1]

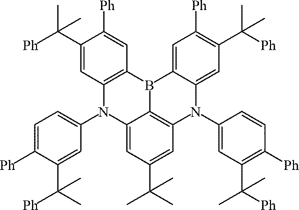 [SMILES: CC(C)(C)c1cc2c3c(c1)N(c1ccc(-c4ccccc4)c(C(C)(C)c4ccccc4)c1)c1cc(C(C)(C)c4ccccc4)c(-c4ccccc4)cc1B3c1cc(-c3ccccc3)c(C(C)(C)c3ccccc3)cc1N2c1ccc(-c2ccccc2)c(C(C)(C)c2ccccc2)c1]

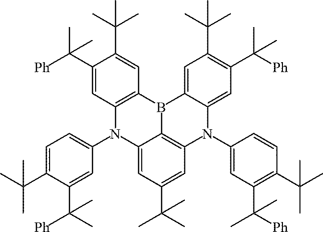 [SMILES: CC(C)(C)c1cc2c3c(c1)N(c1ccc(C(C)(C)C)c(C(C)(C)c4ccccc4)c1)c1cc(C(C)(C)c4ccccc4)c(C(C)(C)C)cc1B3c1cc(C(C)(C)C)c(C(C)(C)c3ccccc3)cc1N2c1ccc(C(C)(C)C)c(C(C)(C)c2ccccc2)c1]

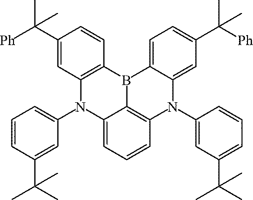 [SMILES: CC(C)(C)c1cccc(N2c3cc(C(C)(C)c4ccccc4)ccc3B3c4ccc(C(C)(C)c5ccccc5)cc4N(c4cccc(C(C)(C)C)c4)c4cccc2c43)c1]

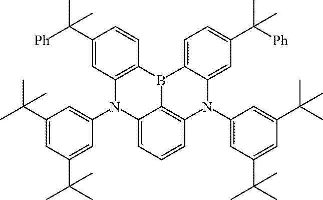 [SMILES: CC(C)(C)c1cc(N2c3cc(C(C)(C)c4ccccc4)ccc3B3c4ccc(C(C)(C)c5ccccc5)cc4N(c4cc(C(C)(C)C)cc(C(C)(C)C)c4)c4cccc2c43)cc(C(C)(C)C)c1]

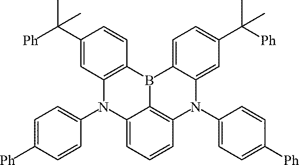 [SMILES: CC(C)(c1ccccc1)c1ccc2c(c1)N(c1ccc(-c3ccccc3)cc1)c1cccc3c1B2c1ccc(C(C)(C)c2ccccc2)cc1N3c1ccc(-c2ccccc2)cc1]

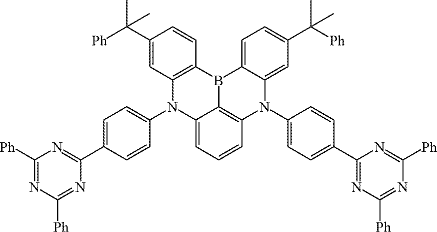 [SMILES: CC(C)(c1ccccc1)c1ccc2c(c1)N(c1ccc(-c3nc(-c4ccccc4)nc(-c4ccccc4)n3)cc1)c1cccc3c1B2c1ccc(C(C)(C)c2ccccc2)cc1N3c1ccc(-c2nc(-c3ccccc3)nc(-c3ccccc3)n2)cc1]

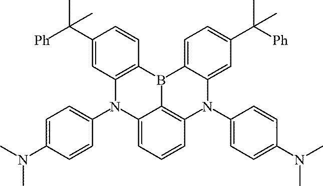

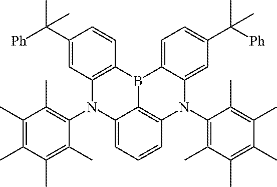

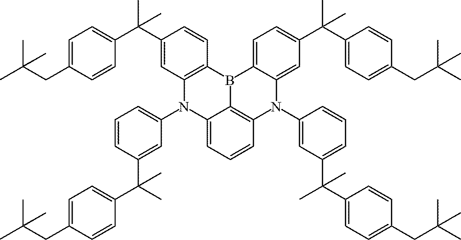 [SMILES: CC(C)(C)Cc1ccc(C(C)(C)c2cccc(N3c4cc(C(C)(C)c5ccc(CC(C)(C)C)cc5)ccc4B4c5ccc(C(C)(C)c6ccc(CC(C)(C)C)cc6)cc5N(c5cccc(C(C)(C)c6ccc(CC(C)(C)C)cc6)c5)c5cccc3c54)c2)cc1]

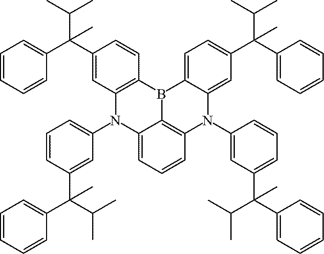

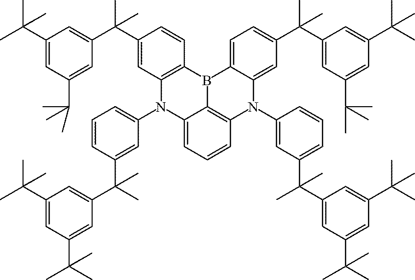

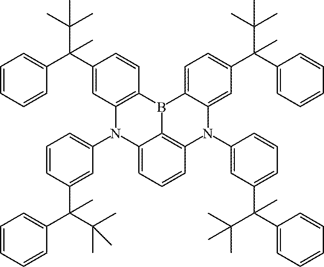

1. An organic molecule, comprising a structure of Formula I: 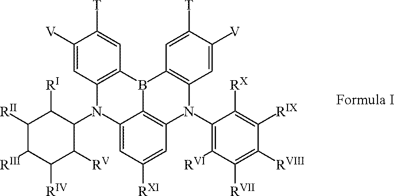
wherein in Formula I,
either both T groups are R¹ or both V groups are R¹ and a remaining T groups or V groups that are not R¹ are each independently selected from the group consisting of:
hydrogen;
deuterium;
C₁-C₅-alkyl; and
Ph, which is optionally substituted with one or more substituents independently from each other selected from the group consisting of Me, ⁱPr, ^{t}Bu, and Ph;
wherein
R¹ comprises or consists of a structure of Formula F: 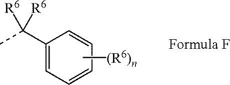
wherein in Formula F,
n is an integer, which is at each occurrence independently selected from the group consisting of 0, 1, 2, 3, 4 and 5; and the dotted line represents a position at which it is bonded to the structure shown in Formula I;
R⁶ is at each occurrence independently from each other selected from the group consisting of
hydrogen, deuterium, and C₁-C₅-alkyl;
R^{I}, R^{II}, R^{III}, R^{IV}, R^{v}, R^{VI}, R^{VII}, R^{VIII}, R^{IX} and R^{X} are each independently selected from the group consisting of:
R¹;
hydrogen;
deuterium;
N(R⁵)₂;
OR⁵;
SR⁵;
Si(R⁵)₃;
B(OR⁵)₂;
OSO₂R⁵;
CF₃;
CN;
halogen;
C₁-C₄ₒ-alkyl,
which is optionally substituted with one or more substituents R⁵ and
wherein one or more non-adjacent CH₂-groups are optionally substituted by R⁵C=CR⁵, C═C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-alkoxy,
which is optionally substituted with one or more substituents R⁵ and
wherein one or more non-adjacent CH₂-groups are optionally substituted by R⁵C=CR⁵, C═C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-thioalkoxy,
which is optionally substituted with one or more substituents R⁵ and
wherein one or more non-adjacent CH₂-groups are optionally substituted by R⁵C=CR⁵, C═C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkenyl,
which is optionally substituted with one or more substituents R⁵ and
wherein one or more non-adjacent CH₂-groups are optionally substituted by R⁵C=CR⁵, C═C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkynyl,
which is optionally substituted with one or more substituents R⁵ and
wherein one or more non-adjacent CH₂-groups are optionally substituted by R⁵C=CR⁵, C═C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀-aryl,
which is optionally substituted with one or more substituents R⁵; and C3-C57-heteroaryl,
which is optionally substituted with one or more substituents R⁵;
R⁵ is at each occurrence independently from one another selected from the group consisting of:
hydrogen, deuterium, OPh, SPh, CF₃, CN, F, Si(C₁-C₅-alkyl)₃, Si(Ph)₃; C₁-C₅-alkyl,
wherein optionally one or more hydrogen atoms are independently from each other substituted by deuterium, CN, CF₃, or F;
C₁-C₅-alkoxy,
wherein optionally one or more hydrogen atoms are independently from each other substituted by deuterium, CN, CF₃, or F;
C₁-C₅-thioalkoxy,
wherein optionally one or more hydrogen atoms are independently from each other substituted by deuterium, CN, CF₃, or F;
C₂-C₅-alkenyl,
wherein optionally one or more hydrogen atoms are independently from each other substituted by deuterium, CN, CF₃, or F;
C₂-C₅-alkynyl,
wherein optionally one or more hydrogen atoms are independently from each other substituted by deuterium, CN, CF₃, or F;
C₆-C₁₈-aryl,
which is optionally substituted with one or more C₁-C₅-alkyl substituents;
C₃-C₁₇-heteroaryl,
which is optionally substituted with one or more C₁-C₅-alkyl substituents;
N(C₆-C₁₈-aryl)₂;
N(C₃-C₁₇-heteroaryl)₂; and
N(C₃-C₁₇-heteroaryl)(C₆-C₁₈-aryl); and
R^{XI} is selected from the group consisting of hydrogen, deuterium, chloride and C₁-C₅ alkyl.

2. The organic molecule according to claim 1, wherein R^{I}, R^{II}, R^{III}, R^{IV}, R^{V}, R^{VI}, R^{VII}, R^{VIII}, R^{IX} and R^{X} are each independently selected from the group consisting of:
R¹,
hydrogen, deuterium, halogen, Me, ⁱPr, ^{t}Bu, CN, CF₃, SiMe₃, SiPh₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

3. The organic molecule according to claim 1, wherein T and V are each independently selected from the group consisting of:
R¹;
hydrogen, deuterium, Me, ⁱPr, ^{t}Bu, and
Ph, which is optionally substituted with one or more substituents independently from each other selected from the group consisting of Me, ⁱPr, ^{t}Bu, and Ph.

4. The organic molecule according to claim 1, wherein R⁶ is at each occurrence independently from each other selected from the group consisting of:
hydrogen,
deuterium,
Me, ⁱPr, ^{t}Bu, and
neo-pentyl.

5. The organic molecule according to claim 1, wherein R⁶ is at each occurrence independently from each other selected from the group consisting of:
hydrogen and Me.

6. The organic molecule according to claim 1 wherein R^{I}, R^{II}, R^{III}, R^{IV}, R^{V}, R^{VI}, R^{VII}, R^{VIII}, R^{IX} and R^{×} are each independently selected from the group consisting of:
R¹,
hydrogen, deuterium, Me, ⁱPr, ^{t}Bu,
Ph, which is optionally substituted with one or more substituents independently from each other selected from the group consisting of Me, ⁱPr, ^{t}Bu, and Ph, and
N(Ph)₂.

7. The organic molecule according to claim 1, comprising a structure of Formula II: 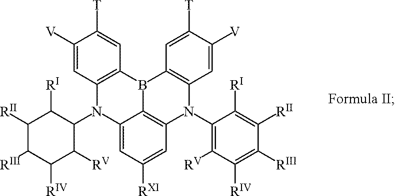
wherein in Formula II, T, V, R^{I} to R^{V}, and R^{XI}are each independently the same as respectively defined in connection with Formula I.

8. The organic molecule according to claim 1, wherein R^{I}, R^{II}, R^{III} and R^{IV} are each independently selected from the group consisting of:
hydrogen, Me, ^{t}Bu, and Ph.

9. The organic molecule according to claim 1, wherein R^{XI} is selected from the group consisting of hydrogen, Me, ⁱPr and ^{t}Bu.

10. An optoelectronic device comprising the organic molecule according to 1 as a luminescent emitter.

11. The optoelectronic device according to claim 10, wherein the optoelectronic device comprises at least one selected from the group consisting of:
organic light-emitting diodes (OLEDs),
light-emitting electrochemical cells,
OLED-sensors,
organic diodes,
organic solar cells,
organic transistors,
organic field-effect transistors,
organic lasers, and
down-conversion elements.

12. A composition, comprising:
(a) the organic molecule according to 1, as an emitter and/or a host, and
(b) an emitter and/or a host material, which differs from the organic molecule, and
(c) optionally, a dye and/or a solvent.

13. An optoelectronic device, comprising the organic molecule according to claim 1,
wherein the device comprises at least one selected from the group consisting of organic light-emitting diodes (OLEDs), light-emitting electrochemical cells, OLED-sensors, organic diodes, organic solar cells, organic transistors, organic field-effect transistors, organic lasers, and down-conversion elements.

14. The optoelectronic device according to claim 13, comprising:
a substrate,
an anode, anda cathode, wherein the anode or the cathode is disposed on the substrate, and
a light-emitting layer between the anode and the cathode and comprising the organic molecule.

15. MethodA method for producing an optoelectronic device, the method comprising depositing the composition according to claim 12 by a vacuum evaporation method or from a solution.

16. A method for producing an optoelectronic device, the method comprising depositing the organic molecule according to claim 1 by a vacuum evaporation method or from a solution.

17. An optoelectronic device, comprising the composition according to claim 12,
wherein the device comprises at least one selected from the group consisting of organic light-emitting diodes (OLEDs), light-emitting electrochemical cells, OLED-sensors, organic diodes, organic solar cells, organic transistors, organic field-effect transistors, organic lasers, and down-conversion elements.

18. The optoelectronic device according to claim 17, comprising:
a substrate,
an anode, and
a cathode, wherein the anode or the cathode is disposed on the substrate, and
a light-emitting layer between the anode and the cathode, and comprising the composition.
